(19) United States
(12) Patent Application Publication
(10) Pub. No.: US 2026/0247812 A1
(43) Pub. Date: Aug. 20, 2026

(54) DISPLAY SUBSTRATE, DISPLAY DEVICE AND FABRICATION METHOD OF DISPLAY SUBSTRATE

(71) Applicants: Chengdu BOE Optoelectronics Technology Co., Ltd., Sichuan (CN); BOE TECHNOLOGY GROUP CO., LTD., Beijing (CN)

(72) Inventors: Dongliang LU, Beijing (CN); Liang SONG, Beijing (CN); Sangcheol YI, Beijing (CN); Lihong ZHAO, Beijing (CN); Zihao LIN, Beijing (CN); Jiahao XU, Beijing (CN); Xin LI, Beijing (CN); Pan HOU, Beijing (CN); Long JIANG, Beijing (CN)

(21) Appl. No.: 19/161,122

(22) PCT Filed: Jul. 15, 2024
(86) PCT No.: PCT/CN2024/105414

§ 371 Date: Aug. 29, 2025

(51) Int. Cl. H10K 59/131; H10K 59/12

(52) U.S. Cl. CPC H10K 59/131; H10K 59/1201

(57) ABSTRACT

At least one of plurality of pads in a first frame area of a display substrate includes: a first insulating layer on a side of the plurality of data line leads away from the base substrate, the first insulating layer comprising a first opening exposing; a first metal layer on a side of the plurality of data line leads away from the base substrate; and a second insulating layer on a side of the first metal layer and the first insulating layer away from the base substrate, the second insulating layer includes a second opening exposing at least a part of the first bottom portion of the first metal layer, and an orthographic projection of the second insulating layer on the base substrate covers the orthographic projections of the first step portion and the second step portion of the first metal layer on the base substrate.

### RELATED APPLICATIONS

The present application is a 35 U.S.C. 371 national stage application of PCT International Application No. PCT/CN2024/105414, filed on Jul. 15, 2024, the entire disclosure of which is incorporated herein by reference.

### TECHNICAL FIELD

The present disclosure relates to the field of display technology, especially a display substrate, a display device and a fabrication method of the display substrate.

### BACKGROUND

Active matrix organic light emitting diode (AMOLED) display panel has the characteristics of flexibility, lightness, active light emission, high brightness, fast response and bendability, and is widely used in electronic products. With the increasing number of signal lines in the display panel, in order to achieve the narrow border effect, it is necessary to arrange the signal lines in different layers. In the frame area of the display substrate, some pads used to connect with the driving chip are prepared synchronously by using the fabricating process of multi-layer signal lines, and the stacking of multiple film layers will lead to the problem of too large step difference (that is, the height difference of different positions of the film layer is too large).

### SUMMARY

According to an aspect of the present disclosure, a display substrate is provided. The display substrate comprises: a base substrate, comprising a display area and a first frame area on at least one side of the display area; a plurality of sub-pixels on a side of the base substrate and in the display area; a plurality of data lines in the display area and electrically connected with the plurality of sub-pixels; a plurality of data line leads in the first frame area and electrically connected with the plurality of data lines; a plurality of pads in the first frame area and electrically connected with the plurality of data line leads; wherein at least one of the plurality of pads comprises: a first insulating layer on a side of the plurality of data line leads away from the base substrate, the first insulating layer comprising a first opening exposing at least a part of at least one of the plurality of data line leads; a first metal layer on a side of the plurality of data line leads away from the base substrate and electrically connected with at least one of the plurality of data line leads through the first opening; wherein the first metal layer comprises a first bottom portion and a step portion surrounding the first bottom portion, an orthographic projection of the first bottom portion on the base substrate is within an orthographic projection of the first opening on the base substrate, and the first bottom portion is electrically connected with at least one of the plurality of data line leads, the step portion comprises a first step portion on a side of the first insulating layer away from the base substrate and a second step portion forming an included angle with the first step portion, wherein the second step portion connects the first bottom portion and the first step portion, and an orthographic projection of the second step portion on the base substrate is within the orthographic projection of the first opening on the base substrate; and a second insulating layer on a side of the first metal layer and the first insulating layer away from the base substrate, wherein the second insulating layer comprises a second opening exposing at least a part of the first bottom portion of the first metal layer, and an orthographic projection of the second insulating layer on the base substrate covers the orthographic projections of the first step portion and the second step portion of the first metal layer on the base substrate.

In some embodiments, the orthographic projection of the second insulating layer on the base substrate partially overlaps with the orthographic projection of the first bottom portion on the base substrate, and an orthographic projection of the second opening on the base substrate is within the orthographic projection of the first opening on the base substrate.

In some embodiments, the display substrate further comprises a second metal layer on a side of the first metal layer and the second insulating layer away from the base substrate, wherein the second metal layer and the first metal layer are electrically connected through the second opening, and an orthographic projection of the second metal layer on the base substrate does not overlap with the orthographic projection of the first step portion of the first metal layer on the base substrate, and the orthographic projection of the second metal layer on the base substrate covers the orthographic projection of the second opening on the base substrate.

In some embodiments, the display substrate further comprises a third metal layer on a side of the second metal layer away from the base substrate, wherein the third metal layer is electrically connected with the second metal layer, and an orthographic projection of the third metal layer on the base substrate covers the orthographic projection of the second metal layer on the base substrate.

In some embodiments, the orthographic projection of the third metal layer on the base substrate does not overlap with the orthographic projection of the first step portion of the first metal layer on the base substrate, and the orthographic projection of the third metal layer on the base substrate is within the orthographic projection of the first opening on the base substrate.

In some embodiments, the orthographic projection of the third metal layer on the base substrate covers the orthographic projection of the first metal layer on the base substrate.

In some embodiments, the orthographic projection of the third metal layer on the base substrate is within the orthographic projection of the first metal layer on the base substrate and partially overlaps with the orthographic projection of the first step portion on the base substrate In some embodiments, the second insulating layer is an inorganic insulating layer or an organic insulating layer.

In some embodiments, the second insulating layer is an organic insulating layer, and the orthographic projection of the third metal layer on the base substrate covers the orthographic projection of the second insulating layer on the base substrate.

In some embodiments, the second insulating layer comprises a first insulating sublayer and a second insulating sublayer, and the second insulating sublayer is on a side of the first insulating sublayer away from the base substrate.

In some embodiments, a material of the first insulating sublayer is an inorganic material, and a material of the second insulating sublayer is an organic material.

In some embodiments, orthographic projections of the first insulating sublayer and the second insulating sublayer on the base substrate both covers the orthographic projections of the first step portion and the second step portion of the first metal layer on the base substrate.

In some embodiments, the orthographic projection of the first insulating sublayer on the base substrate covers the orthographic projections of the first step portion and the second step portion of the first metal layer on the base substrate, and the orthographic projection of the second insulating sublayer on the base substrate does not overlap with the orthographic projection of the first opening on the base substrate.

In some embodiments, a material of the first insulating sublayer is an organic material, and a material of the second insulating sublayer is an inorganic material, and orthographic projections of the first insulating sublayer and the second insulating sublayer on the base substrate both covers the orthographic projections of the first step portion and the second step portion of the first metal layer on the base substrate.

In some embodiments, the display substrate further comprises a third insulating layer on a side of the third metal layer away from the base substrate, wherein the third insulating layer comprises a third opening; and a fourth metal layer on a side of the third metal layer and the third insulating layer away from the base substrate, wherein the fourth metal layer is electrically connected with the third metal layer through the third opening.

In some embodiments, the orthographic projection of the first opening on the base substrate is within an orthographic projection of the third opening on the base substrate, and an orthographic projection of the fourth metal layer on the base substrate covers the orthographic projection of the third metal layer on the base substrate.

In some embodiments, at least one of the plurality of sub-pixels comprises a thin film transistor, the thin film transistor comprises: a gate metal layer on the base substrate, a gate insulating layer on a side of the gate metal layer away from the base substrate, and a first source-drain metal layer, a second source-drain metal layer and a third source-drain metal layer arranged in sequence on a side of the gate insulating layer away from the base substrate.

In some embodiments, the plurality of data line leads are arranged in a same layer as the gate metal layer, the first insulating layer is arranged in a same layer as the gate insulating layer, the first metal layer is arranged in a same layer as the first source-drain metal layer, the second metal layer is arranged in a same layer as the second source-drain metal layer, and the third metal layer is arranged in a same layer as the third source-drain metal layer.

According to another aspect of the present disclosure, a display device is provided. The display device comprises the above display substrate.

According to another aspect of the present disclosure, a method for fabricating the above display substrate is provided. The method comprises: providing a base substrate, wherein the base substrate comprises a display area and a first frame area on at least one side of the display area; preparing a plurality of sub-pixels, a plurality of data lines and a plurality of data line leads on a side of the base substrate, wherein the plurality of sub-pixels and the plurality of data lines are in the display area and the plurality of sub-pixels and the plurality of data lines are electrically connected, and the plurality of data line leads are in the first frame area and electrically connected with the plurality of data lines; preparing a plurality of pads in the first frame area, and steps of preparing at least one of the plurality of pads comprises: forming a first insulating layer on a side of the plurality of data line leads away from the base substrate, wherein the first insulating layer comprises a first opening exposing at least a part of at least one of the plurality of data line leads; forming a first metal layer on a side of the plurality of data line leads away from the base substrate, wherein the first metal layer is electrically connected with at least one of the plurality of data line leads through the first opening, wherein the first metal layer comprises a first bottom portion and a step portion surrounding the first bottom portion, an orthographic projection of the first bottom portion on the base substrate is within an orthographic projection of the first opening on the base substrate, and the first bottom portion is electrically connected with at least one of the plurality of data line leads, the step portion comprises a first step portion on a side of the first insulating layer away from the base substrate and a second step portion forming an included angle with the first step portion, wherein the second step portion connects the first bottom portion and the first step portion, and an orthographic projection of the second step portion on the base substrate is within the orthographic projection of the first opening on the base substrate; and forming a second insulating layer on a side of the first metal layer and the first insulating layer away from the base substrate, wherein the second insulating layer comprises a second opening exposing at least a part of the first bottom portion of the first metal layer, and an orthographic projection of the second insulating layer on the base substrate covers the orthographic projections of the first step portion and the second step portion of the first metal layer on the base substrate.

In some embodiments, the method further comprises: forming a second metal layer on a side of the first metal layer and the second insulating layer away from the base substrate, wherein the second metal layer and the first metal layer are electrically connected through the second opening, and an orthographic projection of the second metal layer on the base substrate does not overlap with the orthographic projection of the first step portion of the first metal layer on the base substrate, and the orthographic projection of the second metal layer on the base substrate covers the orthographic projection of the second opening on the base substrate.

In some embodiments, the method further comprises: forming a third metal layer on a side of the second metal layer away from the base substrate, wherein the third metal layer is electrically connected with the second metal layer, and an orthographic projection of the third metal layer on the base substrate covers the orthographic projection of the second metal layer on the base substrate.

In some embodiment, forming a second insulating layer on a side of the first metal layer and the first insulating layer away from the base substrate comprises: forming the second insulating layer on the side of the first metal layer and the first insulating layer away from the base substrate by using an inorganic material.

In some embodiment, forming a second insulating layer on a side of the first metal layer and the first insulating layer away from the base substrate comprises: forming the second insulating layer on the side of the first metal layer and the first insulating layer away from the base substrate by using an organic material.

In some embodiment, forming a second insulating layer on a side of the first metal layer and the first insulating layer away from the base substrate comprises: forming a first insulating sublayer on the side of the first metal layer and the first insulating layer away from the base substrate by using an inorganic material; and forming a second insulating sublayer on a side of the first insulating sublayer away from the base substrate by using an organic material.

In some embodiment, forming a second insulating layer on the side of the first metal layer and the first insulating layer away from the base substrate comprises: wherein forming a second insulating layer on a side of the first metal layer and the first insulating layer away from the base substrate comprises: forming a first insulating sublayer on the side of the first metal layer and the first insulating layer away from the base substrate by using an organic material; and forming a second insulating sublayer on a side of the first insulating sublayer away from the base substrate using an inorganic material.

According to another aspect of the disclosure, a method for fabricating the above display substrate is provided. The method comprises: providing a base substrate, wherein the base substrate comprises a display area and a first frame area on at least one side of the display area; preparing a plurality of sub-pixels, a plurality of data lines and a plurality of data line leads on a side of the base substrate, wherein the plurality of sub-pixels and the plurality of data lines are in the display area and the plurality of sub-pixels and the plurality of data lines are electrically connected, and the plurality of data line leads are in the first frame area and electrically connected with the plurality of data lines; preparing a plurality of pads in the first frame area, and steps of preparing at least one of the plurality of pads comprises: forming a first insulating layer on a side of the plurality of data line leads away from the base substrate, wherein the first insulating layer comprises a first opening exposing at least a part of at least one of the plurality of data line leads; forming a first metal layer on a side of the plurality of data line leads away from the base substrate, wherein the first metal layer is electrically connected with at least one of the plurality of data line leads through the first opening, wherein the first metal layer comprises a first bottom portion and a step portion surrounding the first bottom portion, an orthographic projection of the first bottom portion on the base substrate is within an orthographic projection of the first opening on the base substrate, and the first bottom portion is electrically connected with at least one of the plurality of data line leads, the step portion comprises a first step portion on a side of the first insulating layer away from the base substrate and a second step portion forming an included angle with the first step portion, wherein the second step portion connects the first bottom portion and the first step portion, and an orthographic projection of the second step portion on the base substrate is within the orthographic projection of the first opening on the base substrate; and forming a second insulating layer on a side of the first metal layer and the first insulating layer away from the base substrate, wherein the second insulating layer covers an orthographic projection of the first metal layer on the base substrate; forming a second metal layer on a side of the second insulating layer away from the base substrate; removing the second metal layer; forming a third metal layer on the side of the second insulating layer away from the base substrate; removing the third metal layer; and forming a second opening on the second insulating layer, wherein the second opening exposes at least a part of the first bottom portion of the first metal layer, and an orthographic projection of the second insulating layer on the base substrate covers the orthographic projections of the first step portion and the second step portion of the first metal layer on the base substrate.

### BRIEF DESCRIPTION OF THE DRAWINGS

In order to more clearly illustrate the technical solutions in embodiments of the disclosure, the appended drawings needed to be used in the description of the embodiments will be introduced briefly in the following. Obviously, the drawings in the following description are only some embodiments of the disclosure, and for those of ordinary skills in the art, other drawings may be obtained according to these drawings under the premise of not paying out creative work.

FIG. 1A is a schematic diagram of a display substrate according to an embodiment of the present disclosure;

FIG. 1B is another schematic diagram of a display substrate according to an embodiment of the present disclosure;

FIG. 2 is a partial schematic diagram of a first signal access area according to an embodiment of the present disclosure;

FIG. 3 is an enlarged detail view of the area S in FIG. 2;

FIG. 4 is a schematic cross-sectional view taken along line aa′ in the display area of the display substrate shown in FIG. 1A;

FIG. 5(a)-5(e) show schematic cross-sectional views of a pad fabricating process according to an embodiment of the present disclosure;

FIG. 6(a)-6(e) show schematic cross-sectional views of a fabricating process of a pad of a display substrate and a structure of the pad according to an embodiment of the present disclosure;

FIG. 7(a)-7(e) show schematic cross-sectional views of a fabricating process of a pad of a display substrate and a structure of the pad according to an embodiment of the present disclosure;

FIG. 8(a)-8(e) show schematic cross-sectional views of a fabricating process of a pad of a display substrate and a structure of the pad according to an embodiment of the present disclosure;

FIG. 9(a)-9(f) show schematic cross-sectional views of a fabricating process of a pad of a display substrate and a structure of the pad according to an embodiment of the present disclosure;

FIG. 10(a)-10(f) show schematic cross-sectional views of a fabricating process of a pad of a display substrate and a structure of the pad according to an embodiment of the present disclosure;

FIG. 11 shows a schematic cross-sectional view of a pad of a display substrate according to an embodiment of the present disclosure;

FIG. 12 shows a schematic cross-sectional view of a pad of a display substrate according to an embodiment of the present disclosure;

FIG. 13 shows a schematic cross-sectional view of a pad of a display substrate according to an embodiment of the present disclosure;

FIG. 14 shows a schematic cross-sectional view of a display substrate according to an embodiment of the present disclosure.

It should be understood that the drawings are only schematic illustrations of exemplary embodiments of the present disclosure, not limitations of the present disclosure, and do not need to be drawn strictly to scale. In addition, in the drawings, the same or similar reference signs are used to refer to the same or similar components.

### DETAILED DESCRIPTION OF THE DISCLOSURE

In the following, the technical solutions in the embodiments of the disclosure will be described clearly and completely in connection with the drawings in the embodiments of the disclosure. Obviously, the described embodiments are only part of the embodiments of the disclosure, and not all of the embodiments. Based on the embodiments in the disclosure, all other embodiments obtained by those of ordinary skills in the art under the premise of not paying out creative work pertain to the protection scope of the disclosure.

It can be understood that the drawings in the embodiments of the present disclosure are only used to schematically show the connection relationship between various components, and the dimensions of various components in the drawings are not drawn to scale, and their relative position relationship does not necessarily correspond to the actual position.

In this disclosure, unless otherwise specified and limited, the terms “installation”, “link”, “connection” and “fixation” should be broadly understood, for example, they may be fixed connection, detachable connection or integrated; they may be a mechanical connection or an electrical connection; they may be directly connected, or be indirectly connected through an intermediary, may be the internal connection of two elements or the interaction between two elements. For those skilled in the art, the specific meanings of the above terms in this disclosure can be understood according to specific circumstances.

In this disclosure, “electrical connection” includes the case where elements are connected together through elements having certain electrical effects. There is no special restriction on “elements with certain electrical effects” as long as they can send and receive electrical signals between connected components. Examples of “elements with certain electrical effects” include not only electrodes and wires, but also switching elements such as transistors, resistors, inductors, capacitors, and other elements with various functions.

In this disclosure, “film” and “layer” may be interchanged. For example, sometimes “conductive layer” may be replaced by “conductive film”. Similarly, sometimes “insulating film” may be replaced by “insulating layer”.

The “patterning process” mentioned in this disclosure includes film deposition, photoresist coating, mask exposure, development, etching and photoresist stripping. Deposition can adopt any one or more selected from sputtering, evaporation and chemical vapor deposition, coating can adopt any one or more selected from spraying and spin coating, and etching can adopt any one or more selected from dry etching and wet etching. “Film” refers to a layer of film made by depositing or coating a certain material on a substrate. If the “film” does not need a patterning process in the whole fabricating process, it can also be called a “layer”. When the “film” needs a patterning process in the whole fabricating process, it is called “film” before the patterning process and “layer” after the patterning process. The “layer” after the patterning process contains at least one “pattern”.

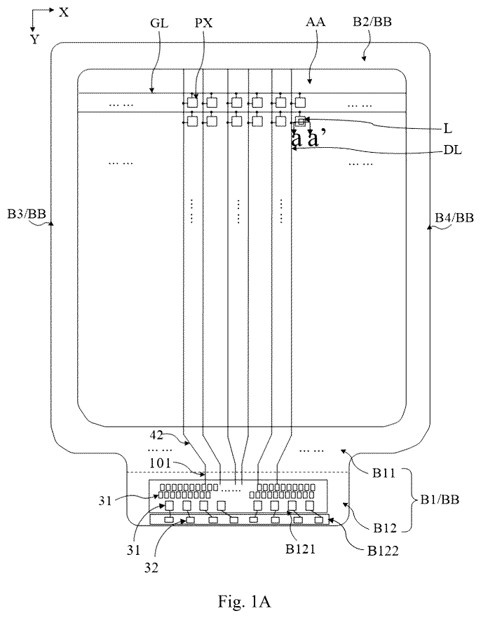

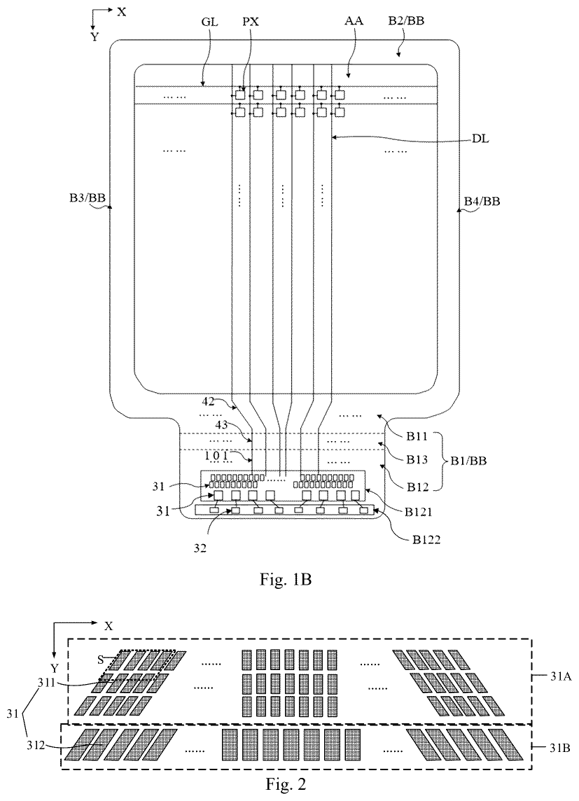

FIG. 1A is a schematic diagram of a display substrate according to an embodiment of the present disclosure. FIG. 1B is another schematic diagram of a display substrate according to an embodiment of the present disclosure. FIGS. 1A and 1B are schematic plan views of the display substrate before the bending process.

In some examples, as shown in FIGS. 1A and 1B, the display substrate may include a display area AA and a peripheral area BB around the periphery of the display area AA. For example, the peripheral area BB may include a first frame area B1 on one side of the display area AA and frame areas on other sides of the display area AA, for example, the peripheral area BB may include a second frame area B2, a third frame area B3 and a fourth frame area B4. Wherein the first frame area B1 may be the lower frame of the display panel, the second frame area B2 may be the upper frame of the display panel, the third frame area B3 may be the left frame of the display panel, and the fourth frame area B4 may be the right frame of the display panel.

In some examples, as shown in FIGS. 1A and 1B, the display area AA may be a flat area including a plurality of sub-pixels PX constituting a pixel array, and the plurality of sub-pixels PX may be configured to display a moving picture or a still image. The display area AA may be called an Active Area. In some examples, the display area AA may be rectangular. However, this embodiment is not limited to this. For example, the display area AA may have other shapes such as a circle or an ellipse. In some examples, the display panel may be a flexible panel, and thus the display panel may be deformable, such as curled, bent, folded or rolled.

In some examples, as shown in FIGS. 1A and 1B, the display area AA may at least include a plurality of sub-pixels PX, a plurality of gate lines GL, and a plurality of data lines DL. The plurality of gate lines GL may extend in a first direction X, and the plurality of data lines DL may extend in a second direction Y. The orthogonal projections of the plurality of gate lines GL and the plurality of data lines DL on the base substrate can cross to form a plurality of sub-pixel regions, and one sub-pixel PX may be set in each sub-pixel region. The plurality of data lines DL and the plurality of sub-pixels PX may be electrically connected, and the plurality of data lines DL may be configured to provide data signals to the plurality of sub-pixels PX. The plurality of gate lines GL may be electrically connected with the plurality of sub-pixels PX, and the plurality of gate lines GL may be configured to provide gate control signals to the plurality of sub-pixels PX. In some examples, the gate control signal may include a scanning signal and a light emission control signal, or may include a scanning signal, a reset control signal and a light emission control signal.

In some examples, as shown in FIGS. 1A and 1B, the first direction X may be the extending direction of the gate lines GL in the display area AA (for example, the row direction), and the second direction Y may be the extending direction of the data lines DL in the display area AA (for example, the column direction). The first direction X and the second direction Y may cross each other, for example, may be perpendicular to each other.

In some examples, a pixel unit of the display area AA may include three sub-pixels, which are red sub-pixels, green sub-pixels and blue sub-pixels, respectively. However, this embodiment is not limited to this. In some examples, a pixel unit may include four sub-pixels, which are red, green, blue and white sub-pixels, respectively.

In some examples, the shape of the sub-pixels may be rectangular, diamond, pentagonal or hexagonal. When a pixel unit includes three sub-pixels, the three sub-pixels may be arranged a horizontal, vertical or triangle manner. When a pixel unit includes four sub-pixels, the four sub-pixels may be arranged in a horizontal, vertical or square manner. However, this embodiment is not limited to this.

In some examples, a sub-pixel may include a pixel circuit and a light emitting element (as indicated by L in FIG. 1A, please note that for simplicity, the light emitting element L is only shown in one sub-pixel PX in FIG. 1A, which does not represent the limitation of this disclosure) electrically connected to the pixel circuit. The pixel circuit may include a plurality of transistors and at least one capacitor. For example, the pixel circuit may have a 3T1C, 4T1C, 5T1C, 5T2C, 6T1C, 7T1C or 8T1C structure. Wherein T in the above circuit structures refers to thin film transistors, and C refers to capacitors. The number before T represents the number of thin film transistors in the circuit, and the number before C represents the number of capacitors in the circuit. In some examples, the plurality of transistors in the pixel circuit may include P-type transistors and N-type transistors. However, this embodiment is not limited to this.

In some examples, a plurality of transistors in the pixel circuit may adopt low-temperature polysilicon thin film transistors and oxide thin film transistors. Low temperature polysilicon (LTPS) is used as the active layer of low temperature polysilicon thin film transistor, and oxide semiconductor is used as the active layer of oxide thin film transistor. Low-temperature polysilicon thin film transistor has the advantages of high mobility and fast charging, while oxide thin film transistor has the advantage of low leakage current. Integrating low-temperature polysilicon thin film transistor and oxide thin film transistor on one display substrate, namely LTPS+Oxide (LTPO for short) display substrate, can make use of their advantages, realize low-frequency driving, reduce power consumption and improve display quality.

In some examples, the light emitting element may be any one of light emitting diode (LED), organic light emitting diode (OLED), quantum dot light emitting diode (QLED), micro LED (including mini-LED or micro-LED) and the like. For example, the light emitting element may be an OLED, and the light emitting element may emit red light, green light, blue light, white light and the like under the drive of its corresponding pixel circuit. The color of the light emitting element can be determined as required. In some examples, the light emitting element may include an anode, a cathode, and an organic light emitting layer between the anode and the cathode. The anode of the light emitting element may be electrically connected with the corresponding pixel circuit. However, this embodiment is not limited to this.

In some examples, the display substrate may integrate a touch structure. The display substrate may include an organic light emitting diode display structure, or a plasma display structure, or an electrophoretic display structure. For example, the display substrate may include an OLED display structure and a touch structure. The touch structure may be arranged on the encapsulation layer of the display structure to form a Touch on Thin Film Encapsulation (Touch on TFE) structure. The display structure and touch structure are integrated, which has the advantages of lightness, thinness and foldability, and can meet the product requirements of flexible folding, narrow borders, etc.

In some examples, the structure of touch structure on thin film package mainly includes Flexible Multi-Layer On Cell (FMLOC) structure and Flexible Single-Layer On Cell (FSLOC) structure. FMLOC structure is based on the working principle of mutual capacitance detection. Generally, two layers of metal are used to form the driving (Tx) electrode and the sensing (Rx) electrode, and the integrated circuit (IC) realizes the touch action by detecting the mutual capacitance between the driving electrode and the sensing electrode. The FSLOC structure is based on the working principle of self-capacitance (or voltage) detection. Generally, a single layer of metal is used to form the touch electrode, and the integrated circuit realizes the touch action by detecting the self-capacitance (or voltage) of the touch electrode.

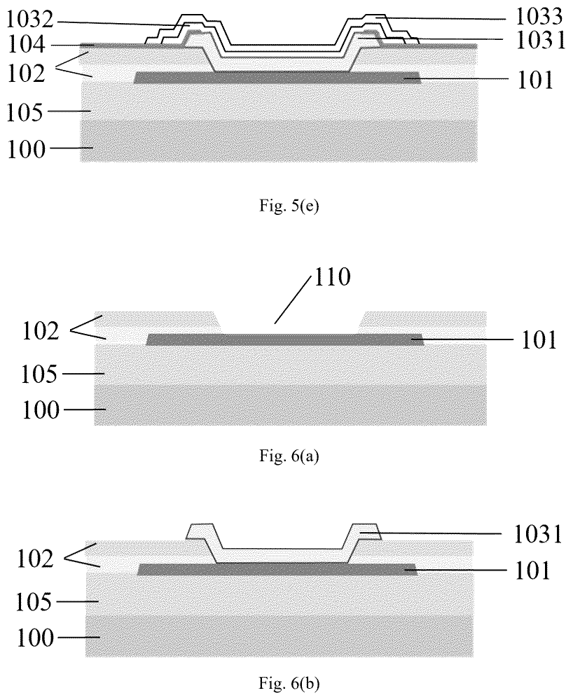

FIG. 4 is a schematic cross-sectional view taken along line aa′ in the display area of the display substrate shown in FIG. 1A. FIG. 4 illustrates the structure of a sub-pixel in the display area as an example. In this example, the types of a plurality of transistors in the pixel circuit are the same, for example, the plurality of transistors in the pixel circuit may all adopt low-temperature polysilicon thin-film transistors or all adopt oxide thin-film transistors. In other examples, the plurality of transistors in the pixel circuit may adopt low-temperature polysilicon thin film transistors and oxide thin film transistors. In addition, this example takes the display panel integrated with the capacitive touch structure to form the FMLOC structure as an example.

In some examples, as shown in FIG. 4, in the direction perpendicular to the display panel, the display area of the display panel may include a base substrate 100, and a circuit structure layer 20, a light emitting structure layer 30, a package structure layer 40, a touch structure layer 50, and a color filter layer 60 sequentially arranged on the base substrate 100. The display structure layer may at least include a circuit structure layer 20 and a light emitting structure layer 30. The circuit structure layer 20 may at least include pixel circuits of a plurality of sub-pixels, and each pixel circuit may include a plurality of transistors and at least one capacitor. The light emitting structure layer 30 may at least include light emitting elements of a plurality of sub-pixels.

In some examples, one thin film transistor 21 and one capacitor 22 included in each sub-pixel are illustrated in FIG. 4. In some examples, the circuit structure layer 20 of the display area may include a semiconductor layer, a first gate metal layer, a second gate metal layer, a first source and drain metal layer, a second source and drain metal layer, and a third source and drain metal layer disposed on the base substrate 100. The plurality of display area metal layers of the display structure layer of this example may include a first gate metal layer, a second gate metal layer, a first source-drain metal layer, a second source-drain metal layer and a third source-drain metal layer. A first gate insulating layer 201 may be arranged between the semiconductor layer and the first gate metal layer, a second gate insulating layer 202 may be arranged between the first gate metal layer and the second gate metal layer, an interlayer insulating layer 203 may be arranged between the second gate metal layer and the first source-drain metal layer, a passivation layer 204 and a first passivation layer 205 may be arranged between the first source-drain metal layer and the second source-drain metal layer, a second passivation layer 206 may be disposed between the second source-drain metal layer and the third source-drain metal layer, and a third passivation layer 207 may be disposed on a side of the third source-drain metal layer away from the base substrate 100. The first gate insulating layer 201, the second gate insulating layer 202, the interlayer insulating layer 203 and the passivation layer 204 may be inorganic insulating layers, and the first passivation layer 205, the second passivation layer 206 and the third passivation layer 207 may be organic insulating layers. However, this embodiment is not limited to this. In other examples, a buffer layer may be arranged on a side of the semiconductor layer near the base substrate, the buffer layer can prevent harmful substances in the base substrate from invading the inside of the display substrate, and can also increase the adhesion of the film layer in the display substrate on the base substrate. In other examples, a bottom shielding metal layer (BSM) may be arranged on a side of the buffer layer near the base substrate, and the bottom shielding metal layer may be configured to at least partially cover the active layer of the thin film transistor of the pixel circuit, so as to avoid the influence of external light on the performance of the thin film transistor. In other examples, a passivation layer may be omitted between the first source-drain metal layer and the second source-drain metal layer, and only a first passivation layer may be provided between the first source-drain metal layer and the second source-drain metal layer.

In some examples, as shown in FIG. 4, the semiconductor layer of the display area may at least include an active layer 210 of a thin film transistor 21. The active layer 210 of the thin film transistor 21 may include a first region 2101, a second region 2102, and a channel region 2100 between the first region 2101 and the second region 2102. The first gate metal layer may at least include the gate 213 of the thin film transistor 21 and the first plate 221 of the capacitor 22. The orthographic projection of the gate electrode 213 of the thin film transistor 21 on the base substrate 100 may cover the orthographic projection of the channel region 2100 of the active layer 210 on the base substrate 100. The second gate metal layer may at least include a second plate 222 of the capacitor 22. The orthographic projections of the second plate 222 and the first plate 221 of the capacitor 22 on the base substrate 100 may at least partially overlap, for example, they may coincide. The first source-drain metal layer may at least include a source electrode 211 and a drain electrode 212 of the thin film transistor 21. The interlayer insulating layer 203 may be provided with a plurality of vias (including a first pixel via and a second pixel via, for example) in the display area, and the interlayer insulating layer 203, the second gate insulating layer 202 and the first gate insulating layer 201 in the first pixel via may be removed, exposing at least part of the surface of the first region 2101 of the active layer 210; the interlayer insulating layer 203, the second gate insulating layer 202 and the first gate insulating layer 201 in the second pixel via may be removed, exposing at least part of the surface of the second region 2102 of the active layer 210. The source electrode 211 of the thin film transistor 21 may be electrically connected to the first region 2101 of the active layer 210 through a first pixel via, and the drain electrode 212 may be electrically connected to the second region 2102 of the active layer 210 through a second pixel via. The second source-drain metal layer may at least include a first switching electrode 231. The first switching electrode 231 may be electrically connected with the drain electrode 212 of the thin film transistor 21 of the pixel circuit through a third pixel via disposed in the passivation layer 204 and the first passivation layer 205. The third source-drain metal layer may at least include a second switching electrode 232. The second switching electrode 232 may be electrically connected with the first switching electrode 231 in the second source-drain metal layer through a fourth pixel via disposed in the second passivation layer 206. The second switching electrode 231 may be electrically connected with the first electrode 301 (e.g., anode) of the light emitting element through a fifth pixel via disposed in the third passivation layer 207. In this example, the electrical connection between the pixel circuit and the light emitting element can be realized through the first switching electrode 231 and the second switching electrode 232.

In some examples, the gate lines of the display area may be in the first gate metal layer or the second gate metal layer, the data lines of the display area may be in the second source-drain metal layer or the third source-drain metal layer, and the high-potential power lines of the display area may be in at least one of the second source-drain metal layer and the third source-drain metal layer, for example. This embodiment is not limited to this. The circuit structure layer of this example may include three source-drain metal layers, which can avoid arranging many lines in a single source-drain metal layer, thus facilitating the realization of a narrow frame structure.

In some examples, as shown in FIG. 4, the light emitting structure layer 30 may include a pixel defining layer 304 and a plurality of light emitting elements. For example, each light emitting element may include a first electrode 301, an organic light emitting layer 302, and a second electrode 303 stacked. The first electrode 301 of the light emitting element may be an anode, and the first electrode 301 may be arranged on the third passivation layer 207 and electrically connected with the second switching electrode 232 through a fifth pixel via disposed in the third passivation layer 207. The pixel defining layer 304 is disposed on the first electrode 301 and the third passivation layer 207. The pixel defining layer 304 may be provided with a plurality of pixel openings, and one pixel opening may expose at least part of the surface of a corresponding first electrode 301. At least part of the organic light emitting layer 302 may be disposed in one pixel opening and connected with the corresponding first electrode 301. The second electrode 303 may be disposed on the organic light emitting layer 302 and connected to the organic light emitting layer 302. The organic light emitting layer 302 can emit light with corresponding colors driven by the first electrode 301 and the second electrode 303. The side of the pixel defining layer 304 away from the base substrate 100 may also be provided with a separation pillar layer, which may include a plurality of separation pillars (PS).

In some examples, the organic light emitting layer 302 of the light emitting element may include one or more of an emitting layer (EML) and a hole injection layer (HIL), a hole transport layer (HTL), a hole block layer (HBL), electron block layer (EBL), electron injection layer (EIL) and electron transport layer (ETL). Driven by the voltage of the first electrode 301 and the second electrode 303, light can be emitted according to the required gray scale by using the light emitting characteristics of organic materials.

In some examples, light emitting layers of light emitting elements of different colors may be different. For example, a red light emitting element includes a red light emitting layer, a green light emitting element includes a green light emitting layer, and a blue light emitting element includes a blue light emitting layer. In order to reduce the process difficulty and improve the yield, the hole injection layer and the hole transport layer at one side of the light emitting layer may adopt a common layer, and the electron injection layer and the electron transport layer at the other side of the light emitting layer may adopt a common layer. In some examples, any one or more layers of the hole injection layer, the hole transport layer, the electron injection layer and the electron transport layer may be prepared by one-time process (one-time evaporation process or one-time ink-jet printing process), and isolation can be achieved by means of height difference of the formed film layers or surface treatment. For example, any one or more layers of hole injection layer, hole transport layer, electron injection layer and electron transport layer corresponding to adjacent sub-pixels can be isolated. In some examples, the organic light emitting layer may be prepared by vapor deposition using a fine metal mask (FMM) or an open mask, or by an ink-jet process.

In some examples, as shown in FIG. 4, the encapsulation structure layer 40 may include a first encapsulation layer 401, a second encapsulation layer 402 and a third encapsulation layer 403 stacked in the direction perpendicular to the base substrate. Wherein the first encapsulation layer 401 and the third encapsulation layer 403 may be made of inorganic materials such as silicon nitride, silicon oxide, silicon oxynitride, etc., which have high compactness and can prevent the invasion of water and oxygen. The second encapsulation layer 402 may be made of organic materials, and it can be arranged between the first encapsulation layer 401 and the third encapsulation layer 403 to ensure that external water vapor cannot enter the light emitting element. The second encapsulation layer 402 may be made of organic materials, such as a polymer material containing a desiccant or a polymer material that can block water vapor, or a polymer resin, to planarize the surface of the display panel and relieve the stress of the first encapsulation layer 401 and the third encapsulation layer 403, and the second encapsulation layer 402 may also include a water-absorbing material such as a desiccant to absorb substances such as water and oxygen invading the interior. However, this embodiment is not limited to this. For example, the encapsulation structure layer may adopt a five-layer structure of inorganic/organic/inorganic/organic/inorganic.

In some examples, the touch structure layer of the display area may include a plurality of first touch electrodes, a plurality of first connection portions, a plurality of second touch electrodes and a plurality of second connection portions. The plurality of first touch electrodes may be arranged on the same layer, and adjacent first touch electrodes may be connected through first connection portions. The plurality of second touch electrodes may be arranged on the same layer, and adjacent second touch electrodes may be connected through second connection portions.

In some examples, as shown in FIG. 4, in the direction perpendicular to the base substrate, the touch structure layer 50 of the display area may include a touch buffer layer (TBL)501, a first touch conductive layer 511, a touch interlayer insulating layer (TLD)502 and a second touch conductive layer 512, which are sequentially arranged. The touch buffer layer 501 and the touch interlayer insulating layer 502 may be inorganic insulating layers, for example, SiNx layers. For example, the first touch conductive layer 511 may include a plurality of first touch electrodes, a plurality of second touch electrodes and a plurality of first connection portions. The first touch electrodes and the first connection portions may be an integrated structure connected with each other. The second touch conductive layer 512 may include a plurality of second connection portions. A second connection portion may be connected with an adjacent second touch electrode through a via disposed in the touch interlayer insulating layer. However, this embodiment is not limited to this. In other examples, the first touch conductive layer may include a plurality of first touch electrodes, a plurality of second touch electrodes and a plurality of second connection portions, and the second touch electrodes and the second connection portions may be an integral structure connected with each other. The second touch conductive layer may include a plurality of first connection portions, and a first connection portions may be connected with an adjacent first touch electrode through a via disposed in the touch interlayer insulating layer. In some examples, the first touch electrode may be a driving (Tx) electrode and the second touch electrode may be a sensing (Rx) electrode. Alternatively, the first touch electrode may be a sensing (Rx) electrode and the second touch electrode may be a driving (Tx) electrode. This embodiment is not limited to this.

In some examples, the first touch electrode and the second touch electrode may have a rhombus shape, for example, a regular rhombus, a horizontally long rhombus, or a vertically long rhombus. In other examples, the first touch electrode and the second touch electrode may have any one or more of a triangle, a square, a trapezoid, a parallelogram, a pentagon, a hexagon and other polygons, and the embodiments of the present disclosure are not limited herein.

In some examples, the first touch electrode and the second touch electrode may be in the form of transparent conductive electrodes. In other examples, the first touch electrode and the second touch electrode may be in the form of a metal grid, which may be formed by interweaving a plurality of metal lines, and the metal grid may include a plurality of grid patterns, and the grid patterns may be polygons composed of a plurality of metal lines. The first touch electrodes and the second touch electrodes in the form of metal grid have the advantages of small resistance, small thickness and fast response speed.

In some examples, as shown in FIG. 4, in the direction perpendicular to the base substrate, the color filter on encapsulation (COE) 60 may include an insulating layer 601, a color film layer and an overcoat film 602, which are sequentially arranged, wherein the color film layer includes a black matrix 610 and a color filter unit 611 arranged between the black matrix 610, and the color filter unit 611 may be, for example, a red filter unit, a green filter unit or a blue filter unit.

In some examples, as shown in FIG. 1A, the first frame area B1 of the display panel may include a fan-out line area B11 and a signal access area B12 which are sequentially arranged in a direction away from the display area AA. In FIG. 1A, only a few lines in the first frame area are shown for explanation. This example is not limited to the number of lines in the first frame area.

In some examples, as shown in FIG. 1A, the fan-out line area B11 may be connected between the display area AA and the signal access area B12. The fan-out line area B11 may be provided with at least a plurality of data fan-out lines 42. The plurality of data fan-out lines 42 may be electrically connected with the plurality of data lines DL in the display area AA, for example, the plurality of data fan-out lines 42 may be electrically connected with the plurality of data lines DL in one-to-one correspondence. The plurality of data fan-out lines 42 may extend to the signal access area B12 in a fan-out way. The plurality of data fan-out lines 42 and the plurality of data lines DL may be in different film layers, and the data fan-out lines 42 may be connected with the data lines DL through vias disposed in the insulating layer.

In some examples, as shown in FIG. 1A, the signal access area B12 may include at least one first signal access area B121. This example takes one first signal access area as an example for illustration and explanation. In other examples, the display panel is a large-size panel, and the display panel may include a plurality of first signal access areas, and the plurality of first signal access areas may be sequentially arranged along the first direction X.

In some examples, as shown in FIG. 1A, the first signal access area B121 may also be called a driver chip (IC) setting area. The first signal access area B121 may be provided with a plurality of pads 31, the plurality of pads 31 may be configured to be bound with at least one driving chip. The driving chip may be configured to generate a driving signal required for driving the sub-pixels and provide the driving signal to the data lines DL of the display area AA. For example, the driving signal may be a data signal that drives a sub-pixel. In some examples, the driver chip may be a central processing unit, a digital signal processor, a system-on-a-chip (SoC), etc. For example, the driver chip may also include hardware circuits and computer executable codes. Hardware circuits can include conventional VLSI circuits or gate arrays and existing semiconductors such as logic chips and transistors or other discrete components. Hardware circuits may also include field programmable gate arrays, programmable array logic, programmable logic devices, etc.

In some examples, as shown in FIG. 1A, the signal access area B12 may be at least provided with a plurality of data line leads 101, and the plurality of data line leads 101 may be electrically connected with a plurality of data fan-out lines 42 of the fan-out line area B11, for example, in one-to-one correspondence. For example, a data line lead 101 and the connected data fan-out line 42 may be an integrated structure connected with each other. That is, the plurality of data line leads 101 are electrically connected to the plurality of data lines DL through the plurality of data fan-out lines 42, for example, in one-to-one correspondence. The plurality of data line leads 101 may extend into the first signal access area B121 and be electrically connected with the plurality of pads 31 in the first signal access area B121. For example, the plurality of data line leads 101 may be electrically connected to the plurality of pads 31 in one-to-one correspondence, or one data line lead 101 may be electrically connected to at least one pad 31. The data line leads 101 and the data fan-out lines 42 can transmit the data signal provided by the driver chip to the data lines DL in the display area.

In some examples, as shown in FIG. 1B, the first frame area B1 of the display substrate may include a fan-out line area B11, a bending area B13, and a signal access area B12, which are sequentially arranged in a direction away from the display area AA. In FIG. 1B, only a few lines in the first frame area are shown for explanation. This example is not limited to the number of lines in the first frame area.

In some examples, as shown in FIG. 1B, the bending area B13 may be connected between the fan-out line area B11 and the signal access area B12, and may be configured to bend the signal access area B12 to the back of the display area AA. The bending area B13 may be provided with at least a plurality of data bending connection lines 43. One end of a data bending connection line 43 may be connected to a data fan outlet line 42 in the fan-out line area B11, and the other end may be connected to a data line lead 101 in the signal access area B12. The plurality of data bending connection lines 43 may in a same layer, for example, in the first source-drain metal layer or the second source-drain metal layer. The rest of the structure of the first frame area B1 in this example can refer to the description of the previous embodiment, so it is not described here.

As shown in FIGS. 1A and 1B, the signal access area B12 may further include a second signal access area B122, and a plurality of contact pads 32 are arranged in the second signal access area B122, and the plurality of contact pads 32 are used for binding with flexible printed circuit board. The pad described below in this disclosure refers to the pad 31 of the first signal access area B121, and the pad 31 is used for binding with at least one driving chip.

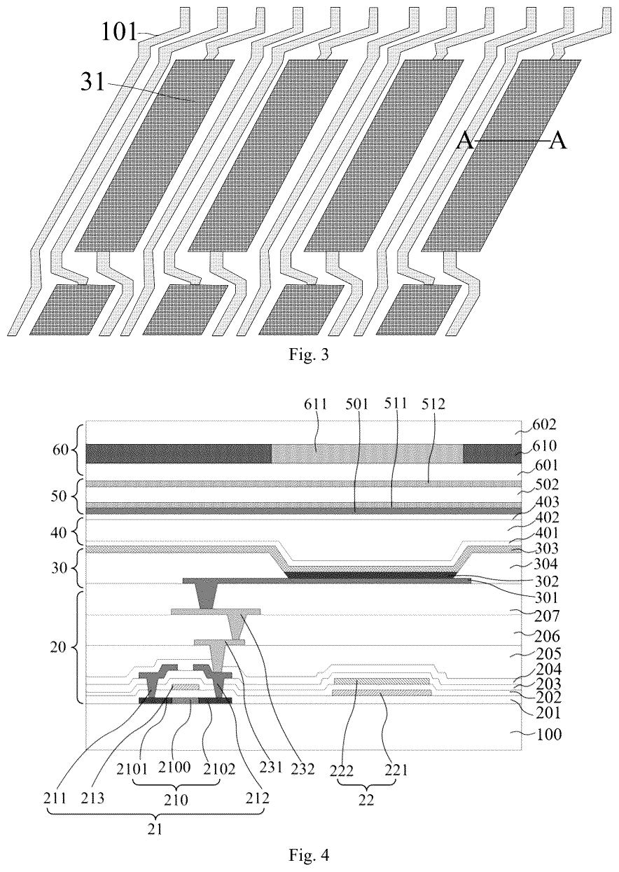

FIG. 2 is a partial enlarged view of a first signal access area according to an embodiment of the present disclosure. In some examples, as shown in FIG. 2, the plurality of pads 31 of the first signal access area B121 may be arranged in a plurality of rows (for example, four rows). The plurality of pads 31 included in each row may be sequentially arranged along the first direction X, and the plurality of rows of pads 31 may be sequentially arranged along the second direction Y. The pads 31 of two adjacent rows may be staggered in the first direction X. However, this embodiment is not limited to this. In other examples, the plurality of pads of the first signal access area B121 may be arranged in one row.

In some examples, the plurality of pads 31 of the first signal access region may be at least divided into a plurality of groups (e.g., two groups). In FIG. 2, two groups of pads (for example, a first group of pads 31A and a second group of pads 31B) are illustrated and explained. The second group of pads 31B may be on the side of the first group of pads 31A away from the display area. The first group of pads 31A may include three rows of pads 311 arranged in the first direction X. The second group of pads 31B may include one row of pads 312 arranged in the first direction X. In some examples, the second group of pads 31B is configured to input signals, which are output to the first group of pads 31A after signal conversion by the bound IC, and the signals (such as data signals) are transmitted to the plurality of sub-pixels PX by the first group of pads 31A through a plurality of signal lines (such as the plurality of data lines DL). The first group of pads 31A and the second group of pads 31B may be staggered in the first direction X. For example, the pads in the first group of pads 31A and the second group of pads 31B may not be aligned in the second direction Y. There are spaces between adjacent pads in the same group, and there are spaces between pads in adjacent groups. In some embodiments, a group of pads may be one row of pads, two rows of pads or three rows of pads. The present disclosure is not limited to the number of rows of pads and the number of pads per row.

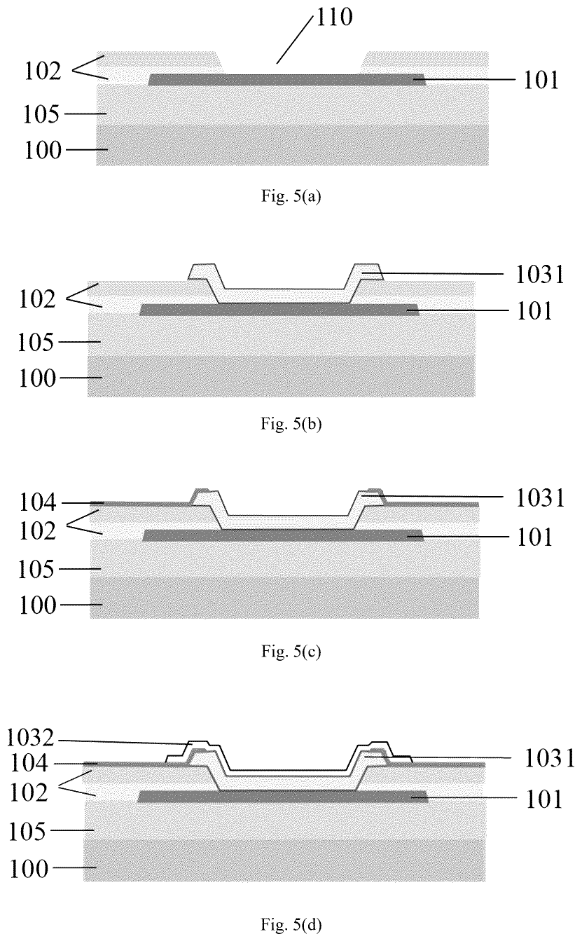

FIG. 3 is an enlarged detail view of the area S in FIG. 2. In some examples, as shown in FIG. 3, the plurality of data line leads 101 may extend in intervals of the plurality of pads 31 generally along the second direction Y. For example, two data line leads 101 may be arranged between two adjacent pads 31 of a group of pads. A data line lead 101 may be electrically connected to at least one pad 31, for example, a data line lead 101 may be connected to one pad 31. The schematic cross-sectional view of the pad referred to below in this disclosure may be taken along the AA line in FIG. 3.

With the increasing number of signal lines in the display panel, in order to achieve the narrow frame effect, it is usually necessary to arrange the signal lines in different layers, for example, to prepare three source-drain metal layers, so that the signal lines can be arranged in the three source-drain metal layers respectively, thereby reducing the load of single-layer and effectively reducing the frame size. In the frame area of the display substrate, some pads used to connect with the driver chip (driver IC) are prepared synchronously by using the fabricating process of three source-drain metal layers. However, the stacking of three film layers will cause the problem of excessive height difference for different positions of the pads.

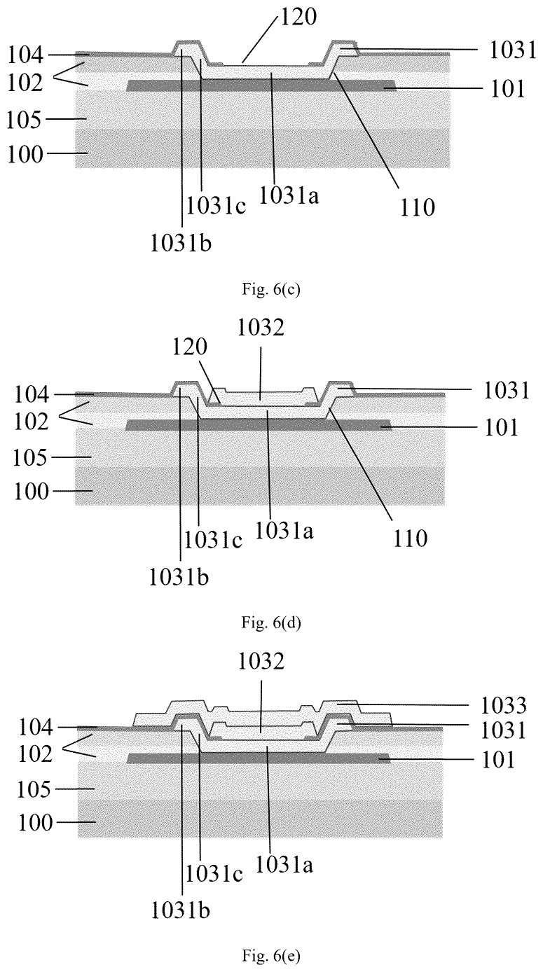

FIG. 5(a)-5(e) show schematic cross-sectional views of a pad fabricating process according to an embodiment of the present disclosure. The steps of fabricating the pad are as follows: preparing a metal film, such as a gate metal film, on a side of the base substrate 100, forming a data line lead 101 as shown in FIG. 5(a) through a patterning process, and then preparing a first insulating layer 102, such as an insulating layer composed of a gate insulating layer and an interlayer insulating layer, and etching to form a first opening 110 exposing at least a part of the data line lead on the first insulating layer 102. Next, a first source-drain metal film is formed on the side of the data line lead 101 and the first insulating layer 102 away from the base substrate 100, and the first source-drain metal film is patterned by a patterning process to form a first metal layer 1031 as shown in FIG. 5(b). Next, a second insulating layer 104, as shown in FIG. 5(c), is formed on the sidewall of the first metal layer 1031 to prevent the metal element (e.g., Al) in the first metal layer from being exposed to cause corrosion or dark spots. Next, a second source-drain metal film is formed, and the second source-drain metal film is patterned by a patterning process to form a second metal layer 1032 as shown in FIG. 5(d). Next, a third source-drain metal film is formed, and the third source-drain metal film is patterned by a patterning process to form a third metal layer 1033 as shown in FIG. 5(e). On the edge around the first opening, a bump formed by stacking the first metal layer 1031, the second metal layer 1032 and the third metal layer 1033 is formed. For the patterning process of the second source-drain metal layer, the thickness of the photoresist is generally 1.2 μm, and the thickness of the photoresist at the bump will be less than 1.2 μm due to the fluidity of the photoresist. When patterning and etching the second source-drain metal layer, the photoresist at the bump will be completely consumed, and then the exposed second metal layer will continue to be etched. This will cause damage to the bump, and the damage may extend along the whole surface of the bump in the second metal layer, which may cause reliability abnormality. Similarly, for the patterning process of the third source-drain metal layer, the thickness of the photoresist is generally 1.5 μm, and the thickness of the photoresist at the bump will be less than 1.5 μm due to the fluidity of the photoresist. When patterning and etching the third source-drain metal layer, the photoresist at the bump will be completely consumed, and then the exposed third metal layer will continue to be etched. This will cause damage to the bump, which may lead to abnormal reliability.

In order to reduce the damage caused by the bump, inventors of the present application adopted a thickened photoresist layer in the patterning process of the second source-drain metal layer and the third source-drain metal layer to solve this problem, for example, the thickness of the photoresist was thickened from 1.2 μm to 1.5 μm in the patterning process of the second source-drain metal layer, and the thickness of the photoresist was thickened from 1.5 μm to 1.8 μm in the patterning process of the third source-drain metal layer. However, with a thickened photoresist, chloride ions in the etching gas will remain in the photoresist, which will cause corrosion of the third metal layer. Thickening photoresist will not only cause the corrosion of the third metal layer, but also bring the following problems: the test time of automatic optic inspection(AOI) equipment is greatly increased; the cost of photoresist increases; Exposure productivity is reduced.

In view of this, the inventors of the present application proposed a method to solve the problem of metal layer damage at the bump without increasing the photoresist thickness. Using the characteristic that the etching selectivity of the source-drain metal layer to the passivation layer is large, the film stacking height is reduced by changing the film structure design at the bump. This pad structure can avoid the damage of metal layer caused by residual chloride ions that cannot be completely removed by using thickened photoresist, and at the same time, it can improve the exposure productivity and reduce the photoresist cost.

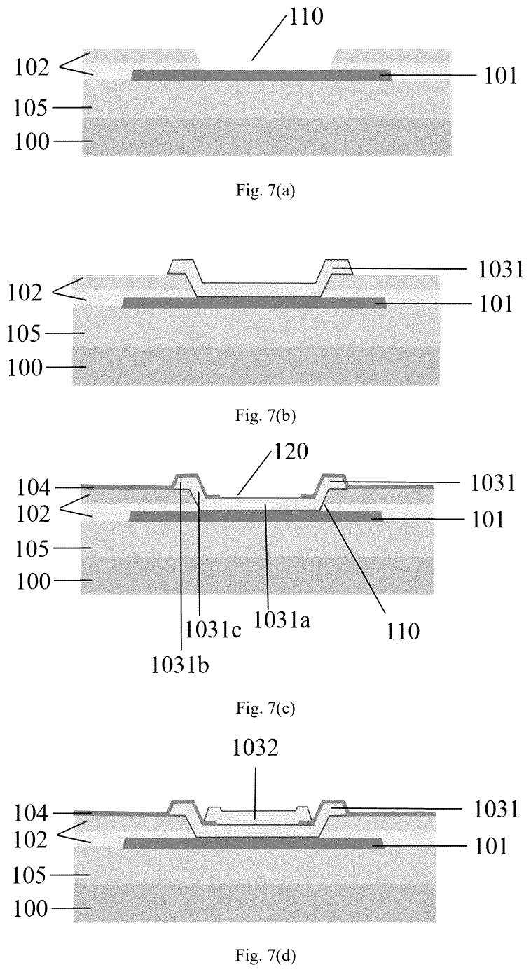

FIG. 6(a)-6(e) show schematic cross-sectional views of a fabricating process of a pad of a display substrate and a structure of the pad according to an embodiment of the present disclosure. As shown in FIG. 6(c), at least one of the plurality of pads of the display substrate provided by the embodiment of the present application includes: a first insulating layer 102 on the side of the plurality of data line leads 101 away from the base substrate 100, wherein the first insulating layer 102 includes a first opening 110 exposing at least a part of at least one of the plurality of data line leads 101; a first metal layer 1031 on the side of the plurality of data line leads 101 away from the base substrate and electrically connected with at least one of the plurality of data line leads 101 through the first opening 110, wherein the first metal layer 1031 includes a first bottom portion 1031a and a step portion surrounding the first bottom portion, the orthographic projection of the first bottom portion 1031a on the base substrate 100 is within the orthographic projection of the first opening 110 on the base substrate 100, and the first bottom portion 1031a is electrically connected with at least one data line lead 101 of the plurality of data line leads, the stepped portion includes a first stepped portion 1031b on the side of the first insulating layer 102 away from the base substrate 100 and a second stepped portion 1031c that forms an included angle with the first stepped portion 1031b, the second stepped portion 1031c connects the first bottom portion 1031a and the first stepped portion 1031b, and the orthographic projection of the second stepped portion 1031c on the base substrate 100 is within the orthographic projection of the first opening 110 on the base substrate 100; and a second insulating layer 104 on the side of the first metal layer 1031 and the first insulating layer 102 away from the base substrate 100, wherein the second insulating layer 104 includes a second opening 120 exposing at least a part of the first bottom portion 1031a of the first metal layer 1031, and the orthographic projection of the second insulating layer 104 on the base substrate 100 covers the orthographic projections of the first stepped portion 1031b and the second stepped portion 1031c of the first metal layer 1031 on the base substrate 100.

In an exemplary embodiment, as shown in FIG. 6(c), the orthographic projection of the second insulating layer 104 on the base substrate 100 may partially overlap the orthographic projection of the first bottom portion 1301a on the base substrate 100, and the orthographic projection of the second opening 120 on the base substrate 100 is within the orthographic projection of the first opening 110 on the base substrate 100.

It should be noted that the sidewall of the first insulating layer facing the first opening has a certain slope, and the second step portion covers the sidewall of the first insulating layer facing the first opening.

In the present disclosure, “the orthographic projection of A covers the orthographic projection of B” means that the boundary of the orthographic projection of B falls within the boundary range of the orthographic projection of A, or the boundary of the orthographic projection of A coincides with the orthographic projection of B. “The orthographic projection of A is within the orthographic projection of B” means that the boundary of the orthographic projection of A falls within the boundary range of the orthographic projection of B.

In an exemplary embodiment, as shown in FIG. 6(d), at least one of the plurality of pads of the display substrate further includes a second metal layer 1032 on the side of the first metal layer 1031 and the second insulating layer 104 away from the base substrate 100, wherein the second metal layer 1032 is electrically connected with the first metal layer 1031 through the second opening 120, the orthographic projection of the second metal layer 1032 on the base substrate 100 does not overlap with the orthographic projection of the first step portion 1031b of the first metal layer 1031 on the base substrate 100, and the orthographic projection of the second metal layer 1032 on the base substrate 100 covers the orthographic projection of the second opening 120 on the base substrate 100, that is, the second metal layer 1032 retracts into the first opening 110.

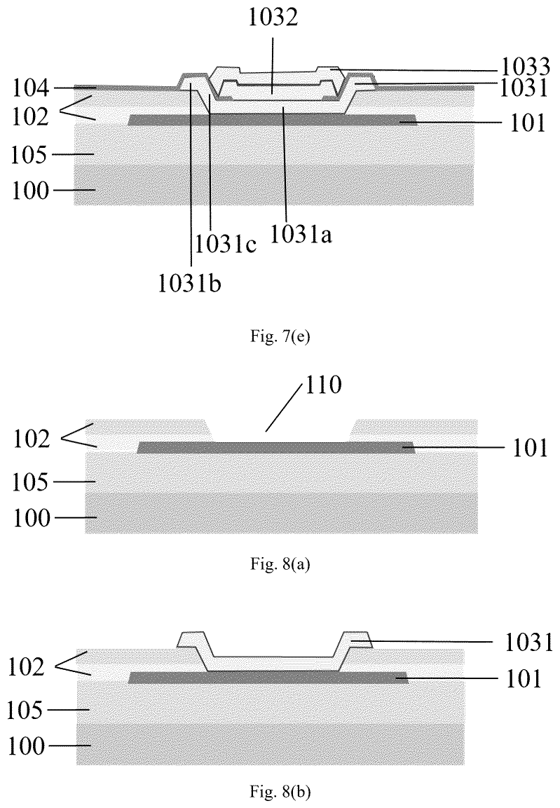

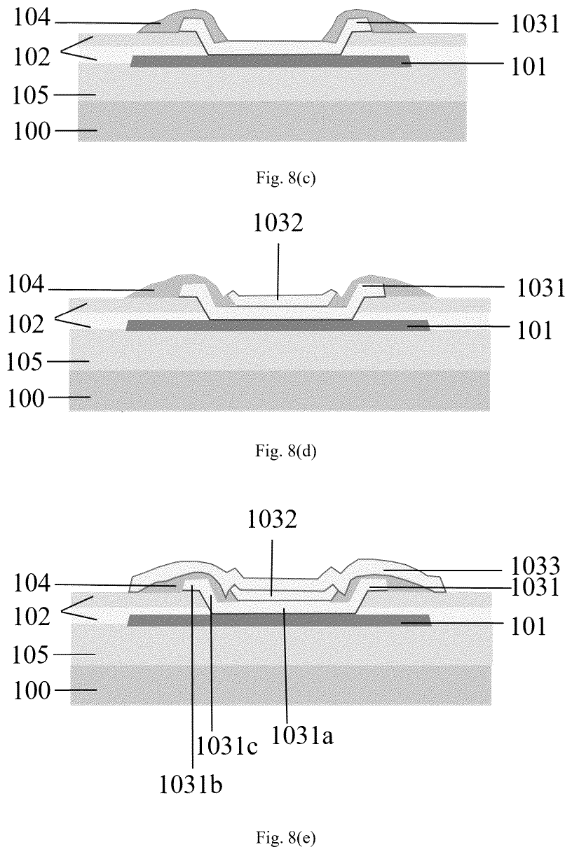

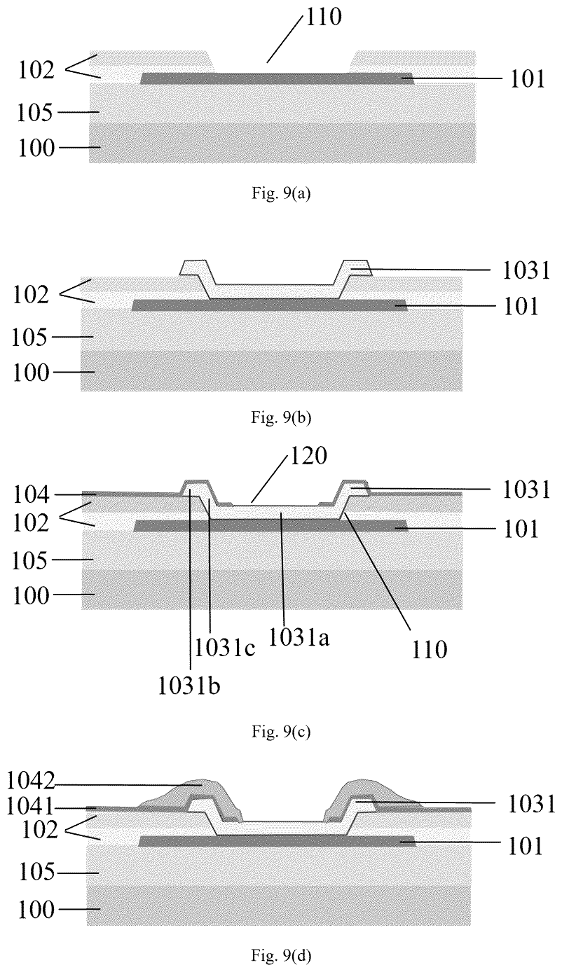

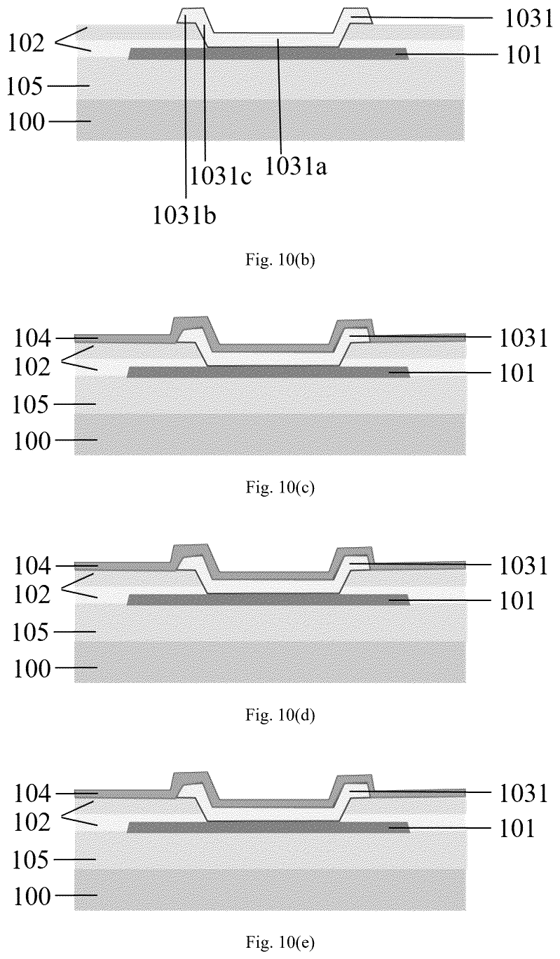

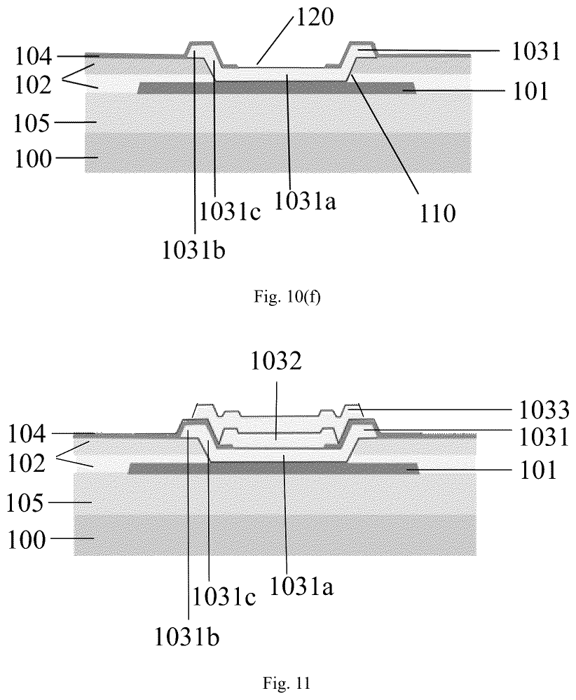

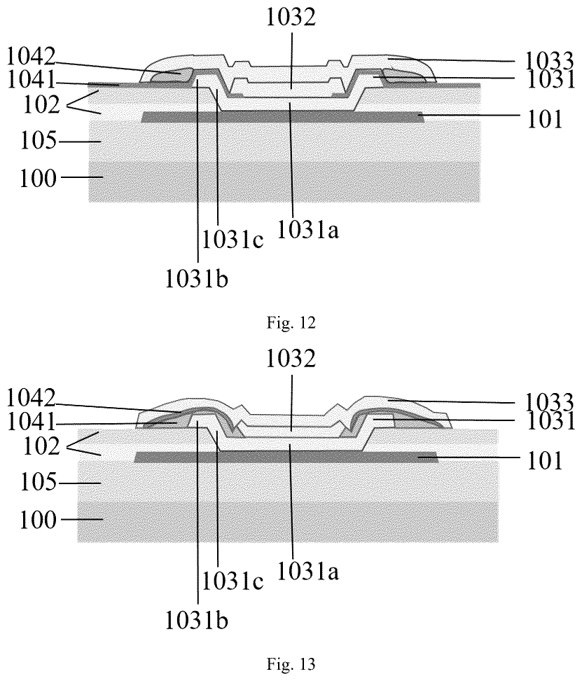

In an exemplary embodiment, as shown in FIG. 6(e), FIG. 7(e), FIG. 8(e), FIG. 9(f), FIG. 11, FIG. 12, and FIG. 13, at least one of the plurality of pads of the display substrate further comprises a third metal layer 1033 on the side of the second metal layer 1032 away from the base substrate 100, wherein the third metal layer 1033 is electrically connected with the second metal layer 1032, and the orthographic projection of the third metal layer 1033 on the base substrate 100 covers the orthographic projection of the second metal layer 1032 on the base substrate.

In the display substrate provided by the present disclosure, the orthographic projection of the second insulating layer 104 on the base substrate 100 covers the orthographic projection of the first step portion 1031b and the second step portion 1031c of the first metal layer 1031 on the base substrate 100, the etching selectivity of the second metal layer 1032 to the second insulating layer 104 is large, that is, when the second metal layer 1032 is etched, the second insulating layer 104 retracted into the first opening 110 can protect the first metal layer 1031 from being affected. Therefore, the second metal layer 1032 is retracted into the first opening 110, thereby reducing the film stacking height of the bump of the pad and solving the problem of metal layer damage at the bump without increasing the photoresist thickness. This pad structure can avoid the damage of metal layer caused by thickening photoresist, improve exposure productivity and reduce photoresist cost.

In an exemplary embodiment, as shown in FIG. 6(e), the orthographic projection of the third metal layer 1033 on the base substrate 100 covers the orthographic projection of the first metal layer 1031 on the base substrate 100. In this embodiment, the second metal layer 1032 retracts into the first opening, and the third metal layer 1033 covers the first metal layer 1031, thus effectively reducing the film stacking height of the bump of the pad. In an exemplary embodiment, as shown in FIG. 7(e), the orthographic projection of the third metal layer 1033 on the base substrate 100 does not overlap with the orthographic projection of the first step portion 1031b of the first metal layer 1031 on the base substrate 100, and the orthographic projection of the third metal layer 1033 on the base substrate 100 is within the orthographic projection of the first opening on the base substrate. In this embodiment, both the second metal layer 1032 and the third metal layer 1033 are retracted into the first opening, which effectively reduces the film stacking height of the bump of the pad.

In an exemplary embodiment, as shown in FIG. 11, the orthographic projection of the third metal layer 1033 on the base substrate 100 is within the orthographic projection of the first metal layer 1031 on the base substrate 100 and partially overlaps with the orthographic projection of the first step portion 1031b on the base substrate 100. In this embodiment, the second metal layer 1032 retracts into the first opening, and the third metal layer 1033 covers a part of the first metal layer 1031, which can also effectively reduce the film stacking height of the bump of the pad.

In some embodiments of the present disclosure, the second insulating layer may be a single-layer insulating layer, which may be an inorganic material insulating layer or an organic material insulating layer. In the pads shown in FIG. 6(e) and 7(e), the second insulating layer 104 is made of inorganic material, while in the pad shown in FIG. 8(e), the second insulating layer 104 is made of organic material. For the organic insulating layer, due to its certain fluidity in the preparation process, it can better fill the height difference of different positions of the film layer, and generally reduce the problem of excessive height difference caused by the stacking of the film layers in the pad more effectively.

In an exemplary embodiment, as shown in FIG. 8(e), the second insulating layer 104 is an organic material insulating layer, and the orthographic projection of the third metal layer 1033 on the base substrate 100 covers the orthographic projection of the first metal layer 1031 on the base substrate 100, and the orthographic projection of the third metal layer 1033 on the base substrate 100 covers the orthographic projection of the second insulating layer 104 on the base substrate 100. However, this is not necessary. In some embodiments, the orthographic projection of the third metal layer on the base substrate may not cover the orthographic projection of the second insulating layer on the base substrate. In some embodiments of the present disclosure, the second insulating layer may include a first insulating sublayer and a second insulating sublayer, and the second insulating sublayer is on a side of the first insulating sublayer away from the base substrate. In an exemplary embodiment, as shown in FIG. 9(f), the material of the first insulating sublayer 1041 is an inorganic material, and the material of the second insulating sublayer 1042 is an organic material. In the pad shown in FIG. 9(f), the orthographic projections of the first insulating sublayer 1041 and the second insulating sublayer 1042 on the base substrate 100 both cover the orthographic projections of the first step portion 1031b and the second step portion 1031c of the first metal layer 1031 on the base substrate 100. Optionally, in the pad shown in FIG. 12, the orthographic projection of the first insulating sublayer 1041 on the base substrate 100 covers the orthographic projections of the first step portion 1031b and the second step portion 1031c of the first metal layer 1031 on the base substrate 100, and the orthographic projection of the second insulating sublayer 1042 on the base substrate 100 does not overlap with the orthographic projection of the first opening on the base substrate 100.

In an exemplary embodiment, as shown in FIG. 13, the material of the first insulating sublayer 1041 is an organic material, and the material of the second insulating sublayer 1042 is an inorganic material. The orthographic projections of the first insulating sublayer 1041 and the second insulating sublayer 1042 on the base substrate 100 both cover the orthographic projections of the first step portion 1031b and the second step portion 1031c of the first metal layer 1031 on the base substrate.

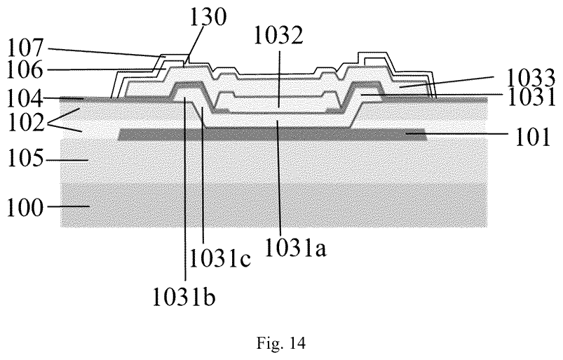

In some embodiments of the present disclosure, as shown in FIG. 14, the pad of the display substrate further includes: a third insulating layer 106 on the side of the third metal layer 1033 away from the base substrate 100, wherein the third insulating layer 106 includes a third opening 130; and a fourth metal layer 107 on the side of the third metal layer 1033 and the third insulating layer 106 away from the base substrate 100, wherein the fourth metal layer 107 is electrically connected with the third metal layer 1033 through the third opening 130.

In an exemplary embodiment, as shown in FIG. 14, the orthographic projection of the first opening on the base substrate 100 is within the orthographic projection of the third opening 130 on the base substrate 100, and the orthographic projection of the fourth metal layer 107 on the base substrate 100 covers the orthographic projection of the third metal layer 1033 on the base substrate 100.

In the present disclosure, at least one sub-pixel in the plurality of sub-pixels in the display area includes a thin film transistor. FIG. 4 is a schematic cross-sectional view taken along line aa′ in the display area of the display substrate shown in FIG. 1A. In FIG. 4, a thin film transistor 21 and a capacitor 22 included in each sub-pixel are illustrated as an example. As mentioned above with reference to FIG. 4, the gate electrode 213 of the thin film transistor 21 and the first plate 221 of the capacitor 22 are in the first gate metal layer, and the side of the first gate metal layer away from the base substrate is provided with the second gate insulating layer 202, and the side of the second gate insulating layer 202 away from the base substrate is provided with the second gate metal layer. The second plate 222 of the capacitor 22 is in the second gate metal layer. The first source-drain metal layer, the second source-drain metal layer and the third source-drain metal layer are arranged in sequence on the side of the second gate metal layer away from the base substrate. The source electrode 211 and the drain electrode 212 of the thin film transistor 21 are in the first source-drain metal layer, the first switching electrode 231 is in the second source-drain metal layer, and the second switching electrode 232 is in the third source-drain metal layer. The interlayer insulating layer 203 may be disposed between the second gate metal layer and the first source-drain metal layer. The pads in the first frame area may be prepared synchronously by using the fabricating process of the elements in the display area. For example, the expression “the plurality of data line leads are arranged in the same layer as the gate metal layer” in this disclosure may include: the plurality of data line leads 101 in the first frame area may be arranged in the same layer as the first gate metal layer; or the plurality of data line leads 101 are arranged alternately one by one in the first gate metal layer and the second gate metal layer. The expression “the first insulating layer is arranged in the same layer as the gate insulating layer” in this disclosure may include that the first insulating layer is arranged in the same layer as the second gate insulating layer and/or the interlayer insulating layer, that is, the “gate insulating layer” here may include the second gate insulating layer 202 and the interlayer insulating layer 203. The first metal layer may be arranged in the same layer as the first source-drain metal layer, the second metal layer may be arranged in the same layer as the second source-drain metal layer, and the third metal layer may be arranged in the same layer as the third source-drain metal layer.

In this disclosure, “A and B are arranged in the same layer” means that A and B use the same film-forming process to form a film layer for forming a specific pattern, and then use the same mask to form a layer structure through one patterning process. Depending on the specific patterns, one patterning process may include multiple exposure, development or etching processes, and the specific patterns in the formed layer structure may be continuous or discontinuous, and these specific patterns may also be at different heights or have different thicknesses.

In the embodiments of the disclosure, the thickness of the first metal layer may be 7000 Å-8000 Å, such as 7100 Å, 7300 Å, 7500 Å, 7800 Å, etc., the thickness of the second metal layer may be 7000 Å-8000 Å, such as 7100 Å, 7300 Å, 7500 Å, 7800 Å, etc., and the thickness of the third metal layer may be 7000 Å-8000 Å, such as 7100 Å, 7300 Å, 7500 Å, 7800 Å, etc. Optionally, the thickness of the second metal layer and the third metal layer may be 7050 Å.

In this disclosure, the gate insulating layer may be a single-layer film or a double-layer film as shown in this disclosure (for example, the first insulating layer 102 in FIG. 6(a)), and those skilled in the art can understand that the double-layer film here may usually be a gate insulating layer (GI) and an interlayer insulating layer (interlayer dielectrics, ILD). A passivation layer is also arranged between the first source-drain metal layer and the second source-drain metal layer of the thin film transistor to protect the sidewall of the first source-drain metal layer. In some embodiments, when the second insulating layer is made of inorganic material, the second insulating layer may be arranged in the same layer as the passivation layer. The thin film transistor may also be provided with a planarization layer as required. In the related art, the planarization layer usually adopts an organic material, and when the second insulating layer is an organic material, the second insulating layer may be arranged in the same layer as the planarization layer. For a touch display substrate, a first touch conductive layer and a second touch conductive layer for touch function, and a touch interlayer insulating layer (touch interlayer dielectrics, TLD) between them are usually provided, and the first touch conductive layer and the second touch conductive layer are electrically connected through vias on the touch interlayer insulating layer. In the present disclosure, the third insulating layer may be arranged in the same layer as the touch interlayer insulating layer, and the fourth metal layer may be arranged in the same layer as one of the first touch conductive layer and the second touch conductive layer. In addition, those skilled in the art can understand that, for example, a barrier layer, a buffer layer, a gate insulating layer, etc. may also be arranged between the base substrate and the plurality of data line leads (i.e., the gate metal layer), as indicated by the film layer 105 in FIG. 6(a). In the present disclosure, the base substrate may be a flexible substrate, specifically, it may be PEN resin, silicon resin, polyimide, etc. The first insulating layer, the second insulating layer and the third insulating layer arranged in the same layer as the passivation layer may adopt any one or more of silicon oxide (SiOx), silicon nitride (SiNx) and silicon oxynitride (SiON), and may be a single layer, a multi-layer or a composite layer. The second insulating layer arranged in the same layer as the planarization layer may be made of organic materials, such as PEN resin, silicon resin, polyimide, etc. The first metal layer, the second metal layer, the third metal layer and the fourth metal layer may be made of metal materials, such as any one or more of silver (Ag), copper (Cu), aluminum (Al) and molybdenum (Mo), or alloy materials of the above metals, such as aluminum-neodymium alloy (AlNd) or molybdenum-niobium alloy (MoNb), and may have a single-layer structure or a multi-layer composite structure, such as Ti/Al/Ti, Mo/Cu/Mo.

According to another aspect of the present disclosure, a display device is provided. The display device comprises the display substrate of the above embodiments. The display device may be a mobile phone, a tablet computer, a television, a monitor, a notebook computer, a digital photo frame, a navigator or any other products or components with display functions.

According to another aspect of the present disclosure, a method for fabricating the above display substrate is provided. FIG. 6(a)-6(e) show schematic cross-sectional views of a fabricating process of a pad of a display substrate and a structure of the pad according to an embodiment of the present disclosure; FIG. 7(a)-7(e) show schematic cross-sectional views of a fabricating process of a pad of a display substrate and a structure of the pad according to another embodiment of the present disclosure; FIG. 8(a)-8(e) show schematic cross-sectional views of a fabricating process of a pad of a display substrate and a structure of the pad according to another embodiment of the present disclosure; FIG. 9(a)-9(f) show schematic cross-sectional views of a fabricating process of a pad of a display substrate and a structure of the pad according to another embodiment of the present disclosure. Specifically, the method comprises: providing a base substrate 100, wherein the base substrate comprises a display area and a first frame area on at least one side of the display area; preparing a plurality of sub-pixels, a plurality of data lines and a plurality of data line leads on a side of the base substrate, wherein the plurality of sub-pixels and the plurality of data lines are in the display area and the plurality of sub-pixels and the plurality of data lines are electrically connected, and the plurality of data line leads are in the first frame area and electrically connected with the plurality of data lines; preparing a plurality of pads in the first frame area, and steps of preparing at least one of the plurality of pads comprises: forming a first insulating layer 102 on a side of the plurality of data line leads 101 away from the base substrate 100, wherein the first insulating layer 102 comprises a first opening 110 exposing at least a part of at least one of the plurality of data line leads 101, as shown in FIG. 6(a), 7(a), 8(a) and 9(a); forming a first metal layer 1031 on a side of the plurality of data line leads 101 away from the base substrate 100, wherein the first metal layer 1031 is electrically connected with at least one of the plurality of data line leads 101 through the first opening 110, wherein the first metal layer comprises a first bottom portion 1031a and a step portion surrounding the first bottom portion, an orthographic projection of the first bottom portion 1031a on the base substrate 100 is within an orthographic projection of the first opening 110 on the base substrate 100, and the first bottom portion 1031a is electrically connected with at least one of the plurality of data line leads 101, the step portion comprises a first step portion 1031b on a side of the first insulating layer 102 away from the base substrate 100 and a second step portion 1031c forming an included angle with the first step portion 1031b, wherein the second step portion 1031c connects the first bottom portion 1031a and the first step portion 1031b, and an orthographic projection of the second step portion 1031c on the base substrate 100 is within the orthographic projection of the first opening 110 on the base substrate 100, as shown in FIG. 6(b), 7(b), 8(b) and 9(b) ; and forming a second insulating layer 104 on a side of the first metal layer1031 and the first insulating layer 102 away from the base substrate 100, wherein the second insulating layer 104 comprises a second opening 120 exposing at least a part of the first bottom portion 1031a of the first metal layer 1031, and an orthographic projection of the second insulating layer 104 on the base substrate 100 covers the orthographic projections of the first step portion 1031b and the second step portion 1031c of the first metal layer 1031 on the base substrate 100, as shown in FIG. 6(c), 7(c), 8(c), 9(c) and 9(d).

In some embodiments, the method further comprises: forming a second metal layer 1032 on the side of the first metal layer 1031 and the second insulating layer 104 away from the base substrate 100, wherein the second metal layer 1032 is electrically connected with the first metal layer 1031 through the second opening 120, the orthographic projection of the second metal layer 1032 on the base substrate 100 does not overlap with the orthographic projection of the first step portion 1031b of the first metal layer 1031 on the base substrate 100, and the orthographic projection of the second metal layer 1032 on the base substrate 100 covers the orthographic projection of the second opening 120 on the base substrate 100, as shown in FIG. 6(d), 7(d), 8(d) and 9(e).

In some embodiments, the method further comprises: forming a third metal layer 1033 on the side of the second metal layer 1032 away from the base substrate 100, wherein the third metal layer 1033 is electrically connected with the second metal layer 1032, and the orthographic projection of the third metal layer 1033 on the base substrate 100 covers the orthographic projection of the second metal layer 1032 on the base substrate 100, as shown in FIG. 6(e), 7(e), 8(e) and 9(f).

In some embodiments, forming the second insulating layer 104 on the side of the first metal layer 1031 and the first insulating layer 102 away from the base substrate 100 comprises: forming the second insulating layer 104 on the side of the first metal layer 1031 and the first insulating layer 102 away from the base substrate 100 by using an inorganic material, forming the structure as shown in FIG. 6(c) and 7(c).

In some embodiments, forming the second insulating layer 104 on the side of the first metal layer 1031 and the first insulating layer 102 away from the base substrate 100 comprises: forming the second insulating layer 104 on the side of the first metal layer 1031 and the first insulating layer 102 away from the base substrate 100 by using an organic material, forming the structure as shown in FIG. 8(c).

In some embodiments, forming the second insulating layer 104 on the side of the first metal layer 1031 and the first insulating layer 102 away from the base substrate 100 comprises: forming a first insulating sublayer 1041 on the side of the first metal layer 1031 and the first insulating layer 102 away from the base substrate 100 by using an inorganic material; and forming a second insulating sublayer 1042 on a side of the first insulating sublayer 1041 away from the base substrate 100 by using an organic material, forming the structure as shown in FIG. 9(d).

In some embodiments, forming the second insulating layer 104 on the side of the first metal layer 1031 and the first insulating layer 102 away from the base substrate 100 comprises: forming a first insulating sublayer 1041 on the side of the first metal layer 1031 and the first insulating layer 102 away from the base substrate 100 by using an organic material; and forming a second insulating sublayer 1042 on a side of the first insulating sublayer 1041 away from the base substrate 100 by using an inorganic material, forming the structure as shown in FIG. 13.

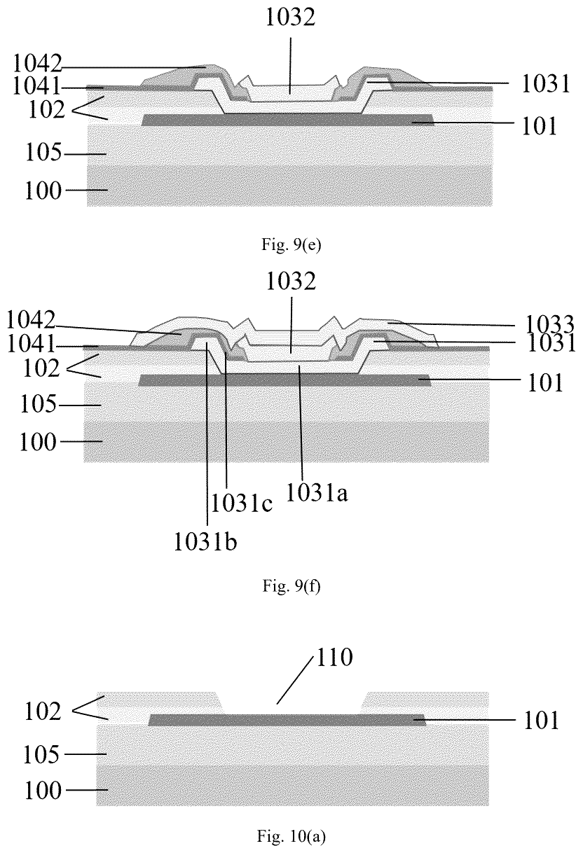

According to another aspect of the disclosure, another method for fabricating the above display substrate is provided. FIG. 10(a)-10(f) show schematic cross-sectional views of a fabricating process of a pad of a display substrate and a structure of the pad according to an embodiment of the present disclosure. Specifically, the method comprises: providing a base substrate 100, wherein the base substrate comprises a display area and a first frame area on at least one side of the display area; preparing a plurality of sub-pixels, a plurality of data lines and a plurality of data line leads on a side of the base substrate, wherein the plurality of sub-pixels and the plurality of data lines are in the display area and the plurality of sub-pixels and the plurality of data lines are electrically connected, and the plurality of data line leads are in the first frame area and electrically connected with the plurality of data lines; preparing a plurality of pads in the first frame area, and steps of preparing at least one of the plurality of pads comprises: forming a first insulating layer 102 on the side of the plurality of data line leads 101 away from the base substrate 100, wherein the first insulating layer 102 comprises a first opening 110 exposing at least a part of at least one of the plurality of data line leads 101, as shown in FIG. 10(a); forming a first metal layer 1031 on a side of the plurality of data line leads 101 away from the base substrate 100, wherein the first metal layer 1031 is electrically connected with at least one of the plurality of data line leads 101 through the first opening 110, wherein the first metal layer comprises a first bottom portion 1031a and a step portion surrounding the first bottom portion, an orthographic projection of the first bottom portion 1031a on the base substrate 100 is within an orthographic projection of the first opening 110 on the base substrate 100, and the first bottom portion 1031a is electrically connected with at least one of the plurality of data line leads 101, the step portion comprises a first step portion 1031b on a side of the first insulating layer 102 away from the base substrate 100 and a second step portion 1031c forming an included angle with the first step portion 1031b, wherein the second step portion 1031c connects the first bottom portion 1031a and the first step portion 1031b, and an orthographic projection of the second step portion 1031c on the base substrate 100 is within the orthographic projection of the first opening 110 on the base substrate 100, as shown in FIG. 10 (b); and forming a second insulating layer 104 on a side of the first metal layer 1031 and the first insulating layer 102 away from the base substrate 100, wherein the second insulating layer 104 covers an orthographic projection of the first metal layer 1031 on the base substrate, as shown in FIG. 10 (c); forming a second metal layer on a side of the second insulating layer 104 away from the base substrate 100; removing the second metal layer, as shown in FIG. 10 (d); forming a third metal layer on the side of the second insulating layer 104 away from the base substrate 100; removing the third metal layer, as shown in FIG. 10 (e) ; and forming a second opening 120 on the second insulating layer 104, wherein the second opening 120 exposes at least a part of the first bottom portion 1031a of the first metal layer 1031, and an orthographic projection of the second insulating layer 104 on the base substrate 100 covers the orthographic projections of the first step portion 1031b and the second step portion 1031c of the first metal layer 1031 on the base substrate, as shown in FIG. 10 (f).

In this method, the second insulating layer completely covers the first metal layer to protect the first metal layer from the etching process of the second metal layer and the third metal layer, and finally an opening exposing at least a part of the first metal layer is formed on the second insulating layer. The pads prepared by this method only have the first metal layer, which avoids the stacking of film layers on the bump and significantly reduces the height difference of different position of pads. However, compared with other above methods, this method needs to add one more mask, and the technicians in the art can choose different fabricating methods according to the actual situation.

The method described above with reference to FIG. 10(a)-FIG. 10(f) is aimed at products with source-drain electrode including a first source-drain metal layer, a second source-drain metal layer and a third source-drain metal layer. If the source-drain electrode only includes one source-drain metal layer, the steps “forming a second metal layer on a side of the second insulating layer 104 away from the base substrate 100; removing the second metal layer” and “forming a third metal layer on the side of the second insulating layer 104 away from the base substrate 100; removing the third metal layer” can be omitted. If the source-drain electrode only includes two source-drain metal layers, the steps “forming a third metal layer on the side of the second insulating layer 104 away from the base substrate 100; removing the third metal layer ”can be omitted.

As mentioned above, the base substrate of the display substrate of the present disclosure may be a flexible substrate. In the fabricating process, a plurality of flexible substrates are usually prepared on a glass substrate, and then the glass substrate is removed after all the display substrates are fabricated. Because the display substrate provided by the present disclosure does not need to thicken photoresist, the exposure productivity in the fabricating process can be improved, the tact time of each layer is reduced by 13 s/Glass, and the photoresist cost is reduced by 18%.

In the drawings, for clarity, the thickness of certain areas and layers may have been exaggerated. The same reference signs in the drawings indicate the same or similar structures, therefore their detailed descriptions will be omitted. The described features, structures, or characteristics may be combined in any suitable manner in one or more embodiments. In the description of the disclosure, many specific details are provided to provide a thorough understanding of the embodiments disclosed herein. However, those skilled in the art will appreciate that the disclosed technical solution may be practiced without one or more of the specific details described, or other methods, components, materials, etc. may be employed. In other cases, well-known structures, materials, or operations are not shown or described in detail to avoid blurring the main technical ideas of the disclosure It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another. Thus, a first element, component, region, layer or section discussed below could be termed a second element, component, region, layer or section without departing from the teachings of the present invention.

Spatially relative terms, such as “row”,“ column”, “below”, “above”, “left”, “right” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. In the description of the specification, the reference to the terms “one embodiment”, “another embodiment”, etc. means that the specific features, structures, materials, or characteristics described in conjunction with that embodiment are included in at least one embodiment disclosed herein. In the specification, the schematic expressions of the above terms do not necessarily refer to the same embodiments or examples. Moreover, the specific features, structures, materials, or characteristics described can be combined in any one or more embodiments or examples in an appropriate manner. In addition, those skilled in the art can combine the different embodiments or examples described in the specification, as well as the features of different embodiments or examples, without conflicting with each other

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present. In no event, however, should “on” or “directly on” be construed as requiring a layer to completely cover an underlying layer.

Embodiments of the invention are described herein with reference to schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Accordingly, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

As will be understood by those skilled in the art, although the various steps of the method disclosed in the disclosure are described in a specific order in the drawings, this does not require or imply that these steps must be performed in that specific order, unless otherwise explicitly stated in the context. Additional or replaceable, multiple steps can be merged into one step for execution, and/or a step can be decomposed into multiple steps for execution. In addition, other method steps can be inserted between the steps. The insertion steps can represent improvements to methods such as those described in the article, or they can be unrelated to the method. Furthermore, the given step may not have been fully completed before the next step begins.

The above embodiments are only used for explanations rather than limitations to the present disclosure, the ordinary skilled person in the related technical field, in the case of not departing from the spirit and scope of the present disclosure, may also make various modifications and variations, therefore, all the equivalent solutions also belong to the scope of the present disclosure, the patent protection scope of the present disclosure should be defined by the claims.

1. A display substrate, comprising:
a base substrate, comprising a display area and a first frame area on at least one side of the display area;
a plurality of sub-pixels on a side of the base substrate and in the display area;
a plurality of data lines in the display area and electrically connected with the plurality of sub-pixels;
a plurality of data line leads in the first frame area and electrically connected with the plurality of data lines;
a plurality of pads in the first frame area and electrically connected with the plurality of data line leads; wherein
at least one of the plurality of pads comprises:
a first insulating layer on a side of the plurality of data line leads away from the base substrate, the first insulating layer comprising a first opening exposing at least a part of at least one of the plurality of data line leads;
a first metal layer on a side of the plurality of data line leads away from the base substrate and electrically connected with at least one of the plurality of data line leads through the first opening; wherein the first metal layer comprises a first bottom portion and a step portion surrounding the first bottom portion, an orthographic projection of the first bottom portion on the base substrate is within an orthographic projection of the first opening on the base substrate, and the first bottom portion is electrically connected with at least one of the plurality of data line leads, the step portion comprises a first step portion on a side of the first insulating layer away from the base substrate and a second step portion forming an included angle with the first step portion, wherein the second step portion connects the first bottom portion and the first step portion, and an orthographic projection of the second step portion on the base substrate is within the orthographic projection of the first opening on the base substrate; and
a second insulating layer on a side of the first metal layer and the first insulating layer away from the base substrate, wherein the second insulating layer comprises a second opening exposing at least a part of the first bottom portion of the first metal layer, and an orthographic projection of the second insulating layer on the base substrate covers the orthographic projections of the first step portion and the second step portion of the first metal layer on the base substrate.

2. The display substrate according to claim 1, wherein the orthographic projection of the second insulating layer on the base substrate partially overlaps with the orthographic projection of the first bottom portion on the base substrate, and an orthographic projection of the second opening on the base substrate is within the orthographic projection of the first opening on the base substrate.

3. The display substrate according to claim 1, further comprising:
a second metal layer on a side of the first metal layer and the second insulating layer away from the base substrate, wherein the second metal layer and the first metal layer are electrically connected through the second opening, and an orthographic projection of the second metal layer on the base substrate does not overlap with the orthographic projection of the first step portion of the first metal layer on the base substrate, and the orthographic projection of the second metal layer on the base substrate covers the orthographic projection of the second opening on the base substrate.

4. The display substrate according to claim 3, further comprising:
a third metal layer on a side of the second metal layer away from the base substrate, wherein the third metal layer is electrically connected with the second metal layer, and an orthographic projection of the third metal layer on the base substrate covers the orthographic projection of the second metal layer on the base substrate.

5. The display substrate according to claim 4, wherein the orthographic projection of the third metal layer on the base substrate does not overlap with the orthographic projection of the first step portion of the first metal layer on the base substrate, and the orthographic projection of the third metal layer on the base substrate is within the orthographic projection of the first opening on the base substrate.

6. The display substrate according to claim 4, wherein the orthographic projection of the third metal layer on the base substrate covers the orthographic projection of the first metal layer on the base substrate.

7. The display substrate according to claim 4, wherein the orthographic projection of the third metal layer on the base substrate is within the orthographic projection of the first metal layer on the base substrate and partially overlaps with the orthographic projection of the first step portion on the base substrate.

8-10. (canceled)

11. The display substrate according to claim 1, wherein the second insulating layer comprises a first insulating sublayer and a second insulating sublayer, and the second insulating sublayer is on a side of the first insulating sublayer away from the base substrate, wherein a material of the first insulating sublayer is an inorganic material, and a material of the second insulating sublayer is an organic material.

12. The display substrate according to claim 11, wherein orthographic projections of the first insulating sublayer and the second insulating sublayer on the base substrate both covers the orthographic projections of the first step portion and the second step portion of the first metal layer on the base substrate.

13. The display substrate according to claim 11, wherein the orthographic projection of the first insulating sublayer on the base substrate covers the orthographic projections of the first step portion and the second step portion of the first metal layer on the base substrate, and the orthographic projection of the second insulating sublayer on the base substrate does not overlap with the orthographic projection of the first opening on the base substrate.

14. The display substrate according to claim 11, wherein a material of the first insulating sublayer is an organic material, and a material of the second insulating sublayer is an inorganic material, and orthographic projections of the first insulating sublayer and the second insulating sublayer on the base substrate both covers the orthographic projections of the first step portion and the second step portion of the first metal layer on the base substrate.

15. The display substrate according to claim 6, further comprising:
a third insulating layer on a side of the third metal layer away from the base substrate, wherein the third insulating layer comprises a third opening; and
a fourth metal layer on a side of the third metal layer and the third insulating layer away from the base substrate, wherein the fourth metal layer is electrically connected with the third metal layer through the third opening.

16. The display substrate according to claim 15, wherein the orthographic projection of the first opening on the base substrate is within an orthographic projection of the third opening on the base substrate, and an orthographic projection of the fourth metal layer on the base substrate covers the orthographic projection of the third metal layer on the base substrate.

17. The display substrate according to claim 4, wherein at least one of the plurality of sub-pixels comprises a thin film transistor, the thin film transistor comprises: a gate metal layer on the base substrate, a gate insulating layer on a side of the gate metal layer away from the base substrate, and a first source-drain metal layer, a second source-drain metal layer and a third source-drain metal layer arranged in sequence on a side of the gate insulating layer away from the base substrate.

18. The display substrate according to claim 17, wherein the plurality of data line leads are arranged in a same layer as the gate metal layer, the first insulating layer is arranged in a same layer as the gate insulating layer, the first metal layer is arranged in a same layer as the first source-drain metal layer, the second metal layer is arranged in a same layer as the second source-drain metal layer, and the third metal layer is arranged in a same layer as the third source-drain metal layer.

19. A display device comprising the display substrate according to claim 1.

20. A method for fabricating the display substrate according to claim 1, comprising:
providing a base substrate, wherein the base substrate comprises a display area and a first frame area on at least one side of the display area;
preparing a plurality of sub-pixels, a plurality of data lines and a plurality of data line leads on a side of the base substrate, wherein the plurality of sub-pixels and the plurality of data lines are in the display area and the plurality of sub-pixels and the plurality of data lines are electrically connected, and the plurality of data line leads are in the first frame area and electrically connected with the plurality of data lines;
preparing a plurality of pads in the first frame area, and steps of preparing at least one of the plurality of pads comprises:
forming a first insulating layer on a side of the plurality of data line leads away from the base substrate, wherein the first insulating layer comprises a first opening exposing at least a part of at least one of the plurality of data line leads;
forming a first metal layer on a side of the plurality of data line leads away from the base substrate, wherein the first metal layer is electrically connected with at least one of the plurality of data line leads through the first opening, wherein the first metal layer comprises a first bottom portion and a step portion surrounding the first bottom portion, an orthographic projection of the first bottom portion on the base substrate is within an orthographic projection of the first opening on the base substrate, and the first bottom portion is electrically connected with at least one of the plurality of data line leads, the step portion comprises a first step portion on a side of the first insulating layer away from the base substrate and a second step portion forming an included angle with the first step portion, wherein the second step portion connects the first bottom portion and the first step portion, and an orthographic projection of the second step portion on the base substrate is within the orthographic projection of the first opening on the base substrate; and
forming a second insulating layer on a side of the first metal layer and the first insulating layer away from the base substrate, wherein the second insulating layer comprises a second opening exposing at least a part of the first bottom portion of the first metal layer, and an orthographic projection of the second insulating layer on the base substrate covers the orthographic projections of the first step portion and the second step portion of the first metal layer on the base substrate.

21. The method of claim 20, further comprising:
forming a second metal layer on a side of the first metal layer and the second insulating layer away from the base substrate, wherein the second metal layer and the first metal layer are electrically connected through the second opening, and an orthographic projection of the second metal layer on the base substrate does not overlap with the orthographic projection of the first step portion of the first metal layer on the base substrate, and the orthographic projection of the second metal layer on the base substrate covers the orthographic projection of the second opening on the base substrate.

22. The method of claim 21, further comprising:
forming a third metal layer on a side of the second metal layer away from the base substrate, wherein the third metal layer is electrically connected with the second metal layer, and an orthographic projection of the third metal layer on the base substrate covers the orthographic projection of the second metal layer on the base substrate.

23-26. (canceled)

27. A method for fabricating the display substrate according to claim 1, comprising:
providing a base substrate, wherein the base substrate comprises a display area and a first frame area on at least one side of the display area;
preparing a plurality of sub-pixels, a plurality of data lines and a plurality of data line leads on a side of the base substrate, wherein the plurality of sub-pixels and the plurality of data lines are in the display area and the plurality of sub-pixels and the plurality of data lines are electrically connected, and the plurality of data line leads are in the first frame area and electrically connected with the plurality of data lines;
preparing a plurality of pads in the first frame area, and steps of preparing at least one of the plurality of pads comprises:
forming a first insulating layer on a side of the plurality of data line leads away from the base substrate, wherein the first insulating layer comprises a first opening exposing at least a part of at least one of the plurality of data line leads;
forming a first metal layer on a side of the plurality of data line leads away from the base substrate, wherein the first metal layer is electrically connected with at least one of the plurality of data line leads through the first opening, wherein the first metal layer comprises a first bottom portion and a step portion surrounding the first bottom portion, an orthographic projection of the first bottom portion on the base substrate is within an orthographic projection of the first opening on the base substrate, and the first bottom portion is electrically connected with at least one of the plurality of data line leads, the step portion comprises a first step portion on a side of the first insulating layer away from the base substrate and a second step portion forming an included angle with the first step portion, wherein the second step portion connects the first bottom portion and the first step portion, and an orthographic projection of the second step portion on the base substrate is within the orthographic projection of the first opening on the base substrate; and
forming a second insulating layer on a side of the first metal layer and the first insulating layer away from the base substrate, wherein the second insulating layer covers an orthographic projection of the first metal layer on the base substrate;
forming a second metal layer on a side of the second insulating layer away from the base substrate;
removing the second metal layer;
forming a third metal layer on the side of the second insulating layer away from the base substrate;
removing the third metal layer; and
forming a second opening on the second insulating layer, wherein the second opening exposes at least a part of the first bottom portion of the first metal layer, and an orthographic projection of the second insulating layer on the base substrate covers the orthographic projections of the first step portion and the second step.
